(19) United States
(12) Patent Application Publication
(10) Pub. No.: US 2024/0258401 A1
(43) Pub. Date: Aug. 1, 2024

(54) SEMICONDUCTOR DEVICE AND SEMICONDUCTOR MEMORY DEVICE

(71) Applicant: Kioxia Corporation, Tokyo (JP)

(72) Inventors: Yusuke NAKAJIMA, Yokkaichi (JP); Akira TAKASHIMA, Fuchu (JP); Tsunehiro INO, Fujisawa (JP); Yasushi NAKASAKI, Yokohama (JP)

(73) Assignee: Kioxia Corporation, Tokyo (JP)

(21) Appl. No.: 18/420,264

(22) Filed: Jan. 23, 2024

(30) Foreign Application Priority Data
Feb. 1, 2023 (JP) 2023-014063

(51) Int. Cl. H01L 29/51; H10B 41/27; H10B 41/35; H10B 43/27; H10B 43/35

(52) U.S. Cl. CPC H01L 29/513; H01L 29/517; H10B 41/27; H10B 41/35; H10B 43/27; H10B 43/35

(57) ABSTRACT

A semiconductor device of embodiments includes: a semiconductor layer; a gate electrode layer including a first conductive layer containing a first material and a second conductive layer between the first conductive layer and the semiconductor layer and containing a second material different from the first material; and a first insulating layer between the semiconductor layer and the gate electrode layer and containing aluminum oxide, the aluminum oxide including α (alpha)-aluminum oxide or θ (theta)-aluminum oxide. The direction of the crystal axis of the aluminum oxide falls within a range of ±10° with respect to a first direction from the semiconductor layer toward the gate electrode layer. The direction of the crystal axis of the first material falls within a range of ±10° with respect to the first direction. The direction of the crystal axis of the second material falls within a range of ±10° with respect to the first direction.

### CROSS-REFERENCE TO RELATED APPLICATION

This application is based upon and claims the benefit of priority from Japanese Patent Application No. 2023-014063, filed on Feb. 1, 2023, the entire contents of which are incorporated herein by reference.

### FIELD

Embodiments described herein relate generally to a semiconductor device and a semiconductor memory device.

### BACKGROUND

For example, a logic device includes a scaled-down metal oxide semiconductor field effect transistor (MOSFET) in order to improve the performance of the device. The scaled-down MOSFET requires a low-resistance gate electrode layer to suppress gate delay and achieve high speed.

In addition, a three-dimensional NAND flash memory in which memory cells are three-dimensionally arranged realizes a high degree of integration and a low cost. In the three-dimensional NAND flash memory, for example, a memory hole penetrating a stacked body is formed in the stacked body in which a plurality of insulating layers and a plurality of gate electrode layers are alternately stacked. By forming a charge storage layer and a semiconductor layer in the memory hole, a memory string in which a plurality of memory cells are connected in series to each other is formed. In the three-dimensional NAND flash memory with scaled-down memory cells, a low-resistance gate electrode layer is required to suppress gate delay and achieve high speed.

### BRIEF DESCRIPTION OF THE DRAWINGS

FIG. 1 is a schematic cross-sectional view of a semiconductor device according to a first embodiment;

FIGS. 2A, 2B, 2C, and 2D are explanatory diagrams of a method for manufacturing the semiconductor device according to the first embodiment;

FIG. 3 is a schematic cross-sectional view of a first modification example of the semiconductor device according to the first embodiment;

FIGS. 4A, 4B, 4C, 4D, and 4E are explanatory diagrams of a method for manufacturing the first modification example of the semiconductor device according to the first embodiment;

FIG. 5 is a schematic cross-sectional view of a second modification example of the semiconductor device according to the first embodiment;

FIG. 6 is a circuit diagram of a memory cell array of a semiconductor memory device according to a second embodiment;

FIGS. 7A and 7B are schematic cross-sectional views of the memory cell array of the semiconductor memory device according to the second embodiment;

FIG. 8 is a schematic cross-sectional view showing an example of a method for manufacturing the semiconductor memory device according to the second embodiment;

FIG. 9 is a schematic cross-sectional view showing an example of the method for manufacturing the semiconductor memory device according to the second embodiment;

FIG. 10 is a schematic cross-sectional view showing an example of the method for manufacturing the semiconductor memory device according to the second embodiment;

FIG. 11 is a schematic cross-sectional view showing an example of the method for manufacturing the semiconductor memory device according to the second embodiment;

FIG. 12 is a schematic cross-sectional view showing an example of the method for manufacturing the semiconductor memory device according to the second embodiment;

FIG. 13 is a schematic cross-sectional view showing an example of the method for manufacturing the semiconductor memory device according to the second embodiment;

FIG. 14 is a schematic cross-sectional view showing an example of the method for manufacturing the semiconductor memory device according to the second embodiment;

FIG. 15 is a schematic cross-sectional view showing an example of the method for manufacturing the semiconductor memory device according to the second embodiment;

FIG. 16 is a schematic cross-sectional view showing an example of the method for manufacturing the semiconductor memory device according to the second embodiment;

FIGS. 17A and 17B are schematic cross-sectional views of a memory cell array of a first modification example of the semiconductor memory device according to the second embodiment;

FIGS. 18A and 18B are schematic cross-sectional views of a memory cell array of a second modification example of the semiconductor memory device according to the second embodiment;

FIG. 19 is a circuit diagram of a memory cell array of a semiconductor memory device according to a third embodiment;

FIG. 20 is a schematic cross-sectional view of the memory cell array of the semiconductor memory device according to the third embodiment;

FIGS. 21A and 21B are schematic cross-sectional views of the memory cell array of the semiconductor memory device according to the third embodiment; and

FIG. 22 is a schematic cross-sectional view of a memory cell array of a modification example of the semiconductor memory device according to the third embodiment.

### DETAILED DESCRIPTION

A semiconductor device of embodiments includes: a semiconductor layer; a gate electrode layer including a first conductive layer containing a first material and a second conductive layer provided between the first conductive layer and the semiconductor layer and containing a second material different from the first material; and a first insulating layer provided between the semiconductor layer and the gate electrode layer and containing aluminum oxide, the aluminum oxide including at least one crystal phase selected from a group consisting of α (alpha)-aluminum oxide and θ (theta)-aluminum oxide. The direction of the crystal axis of the aluminum oxide in the first insulating layer falls within a range of ±10° with respect to a first direction from the semiconductor layer toward the gate electrode layer. The direction of the crystal axis of the first material in the first conductive layer falls within a range of ±10° with respect to the first direction. The direction of the crystal axis of the second material in the second conductive layer falls within a range of ±10° with respect to the first direction.

Hereinafter, embodiments will be described with reference to the diagrams. In addition, in the following description, the same or similar members and the like are denoted by the same reference numerals, and the description of the members and the like once described will be omitted as appropriate.

In addition, in this specification, the term “upper” or “lower” may be used for convenience. “Upper” or “lower” is a term indicating, for example, a relative positional relationship in the diagrams. The term “upper” or “lower” does not necessarily define the positional relationship with respect to gravity.

The qualitative analysis and quantitative analysis of the chemical composition of members forming the semiconductor device or the semiconductor memory device in this specification can be performed by, for example, secondary ion mass spectroscopy (SIMS), energy dispersive X-ray spectroscopy (EDX), and electron energy loss spectroscopy (EELS). In addition, when measuring the thickness of each member forming the semiconductor device or the semiconductor memory device, a distance between members, and the like, it is possible to use, for example, a transmission electron microscope (TEM). In addition, for the identification of the crystal system of the constituent material of each member forming the semiconductor memory device and the comparison of the abundance ratio of the crystal systems, for example, a transmission electron microscope, X-ray diffraction (XRD), electron beam diffraction (EBD), X-ray photoelectron spectroscopy (XPS), or synchrotron radiation X-ray absorption fine structure (XAFS) can be used. In addition, the orientation of the crystal axes can be evaluated by, for example, performing fast Fourier transform analysis on an image obtained by the TEM.

### First Embodiment

A semiconductor device according to a first embodiment includes: a semiconductor layer; a gate electrode layer including a first conductive layer containing a first material and a second conductive layer provided between the first conductive layer and the semiconductor layer and containing a second material different from the first material; and a first insulating layer provided between the semiconductor layer and the gate electrode layer and containing aluminum oxide, the aluminum oxide including at least one crystal phase selected from a group consisting of α (alpha)-aluminum oxide and θ (theta)-aluminum oxide. Then, the direction of the crystal axis of the aluminum oxide in the first insulating layer falls within a range of ±10° with respect to a first direction from the semiconductor layer toward the gate electrode layer. The direction of the crystal axis of the first material in the first conductive layer falls within a range of ±10° with respect to the first direction. The direction of the crystal axis of the second material in the second conductive layer falls within a range of ±10° with respect to the first direction.

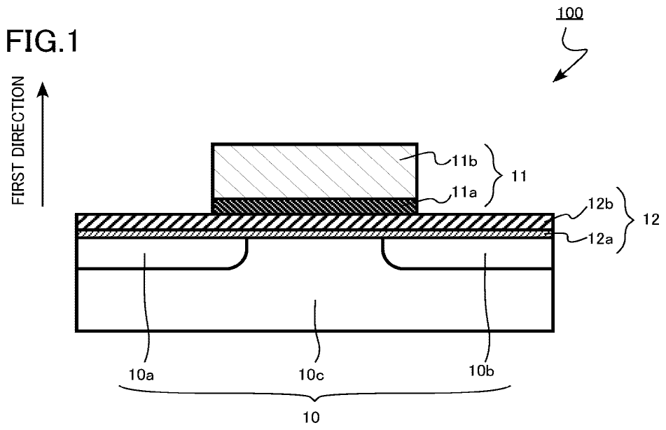

FIG. 1 is a schematic cross-sectional view of the semiconductor device according to the first embodiment. The semiconductor device according to the first embodiment is a MOSFET 100. The MOSFET 100 is a MOSFET having a planar gate structure.

The MOSFET 100 includes a semiconductor layer 10, a gate electrode layer 11, and a gate insulating layer 12. The semiconductor layer 10 includes a source region 10a, a drain region 10b, and a channel region 10c. The gate electrode layer 11 includes a barrier metal layer 11a and a metal layer 11b. The gate insulating layer 12 includes a lower layer 12a and an upper layer 12b.

The barrier metal layer 11a is an example of a second conductive layer. The metal layer 11b is an example of a first conductive layer. The lower layer 12a is an example of a second insulating layer. The upper layer 12b is an example of a first insulating layer.

The semiconductor layer 10 is a semiconductor. The semiconductor layer 10 is, for example, a single crystal. The semiconductor layer 10 is, for example, silicon. The semiconductor layer 10 is, for example, an oxide semiconductor.

The semiconductor layer 10 includes the source region 10a, the drain region 10b, and the channel region 10c. The channel region 10c is provided between the source region 10a and the drain region 10b.

The source region 10a and the drain region 10b are, for example, n-type semiconductors. In addition, the channel region 10c is, for example, a p-type semiconductor.

The gate electrode layer 11 is a conductor. The gate electrode layer 11 includes the barrier metal layer 11a and the metal layer 11b. The barrier metal layer 11a is provided between the metal layer 11b and the semiconductor layer 10. The barrier metal layer 11a is provided between the metal layer 11b and the gate insulating layer 12.

The metal layer 11b contains a first material. The barrier metal layer 11a contains a second material. The first material and the second material are different.

The first material is the main component of the metal layer 11b. The metal layer 11b is formed of, for example, a first material.

The first material is, for example, a metal or a metal compound. The first material is, for example, at least one material selected from a group consisting of molybdenum (Mo) and tungsten (W). The metal layer 11b is, for example, a molybdenum layer or a tungsten layer.

The second material is the main component of the barrier metal layer 11a. The barrier metal layer 11a is formed of, for example, a second material.

The second material is, for example, a metal or a metal compound. The second material is, for example, at least one material selected from a group consisting of molybdenum nitride, titanium nitride, and niobium nitride. The barrier metal layer 11a is, for example, a molybdenum nitride layer, a titanium nitride layer, or a niobium nitride layer.

The gate insulating layer 12 is provided between the semiconductor layer 10 and the gate electrode layer 11. The gate insulating layer 12 includes the lower layer 12a and the upper layer 12b.

The upper layer 12b is provided between the semiconductor layer 10 and the gate electrode layer 11. The lower layer 12a is provided between the semiconductor layer 10 and the upper layer 12b.

The lower layer 12a is an insulating layer. The lower layer 12a contains, for example, silicon (Si) and oxygen (O). The lower layer 12a contains, for example, silicon oxide. The lower layer 12a is, for example, a silicon oxide layer.

The lower layer 12a has, for example, a function of reducing the interface state of the interface between the semiconductor layer 10 and the gate insulating layer 12.

The thickness of the lower layer 12a in a first direction from the semiconductor layer 10 toward the gate electrode layer 11 is, for example, equal to or more than 0.3 nm and equal to or less than 2 nm. The first direction is, for example, a direction perpendicular to the interface between the semiconductor layer 10 and the gate insulating layer 12. The first direction is, for example, a direction perpendicular to the interface between the gate electrode layer 11 and the gate insulating layer 12. The first direction is the thickness direction of the gate insulating layer 12. The first direction is the thickness direction of the upper layer 12b.

The upper layer 12b is an insulating layer. The upper layer 12b contains aluminum oxide. The aluminum oxide is the main component of the upper layer 12b. The upper layer 12b is, for example, an aluminum oxide layer.

The aluminum oxide contained in the upper layer 12b includes at least one crystal phase selected from a group consisting of α (alpha)-aluminum oxide and θ (theta)-aluminum oxide. The aluminum oxide contained in the upper layer 12b contains, for example, both α-aluminum oxide and θ-aluminum oxide.

α-aluminum oxide has a hexagonal crystal structure. θ-aluminum oxide has a monoclinic crystal structure.

The aluminum oxide contained in the upper layer 12b may contain γ (gamma)-aluminum oxide. γ-aluminum oxide has a cubic crystal structure.

α-aluminum oxide is also called α-alumina, θ-aluminum oxide is also called θ-alumina, and γ-aluminum oxide is also called γ-alumina.

The direction of the crystal axis of aluminum oxide in the upper layer 12b falls within a range of ±10° with respect to the first direction. The crystal axis of aluminum oxide is, for example, the a-axis, the b-axis, or the c-axis.

The crystal axis of aluminum oxide in the upper layer 12b is oriented along the first direction. The aluminum oxide in the upper layer 12b is uniaxially oriented. For example, the direction of the c-axis of the aluminum oxide in the upper layer 12b falls within a range of ±10° with respect to the first direction.

The angle between the direction of the crystal axis of aluminum oxide in the upper layer 12b and the first direction can be determined, for example, by comparing the arrangement direction of spots obtained by fast Fourier transform analysis of the TEM image of the cross section of the upper layer 12b with the first direction. For example, the angle between the spot arrangement direction and the first direction is measured at a plurality of locations on the cross section of the upper layer 12b. Then, for example, the average value of the measured angles is determined as the angle between the direction of the crystal axis of aluminum oxide in the upper layer 12b and the first direction.

The thickness of the upper layer 12b in the first direction from the semiconductor layer 10 toward the gate electrode layer 11 is, for example, equal to or more than 0.5 nm and equal to or less than 2.5 nm.

In addition, the MOSFET 100 can have a structure in which the upper layer 12b is in contact with the semiconductor layer 10 by omitting the lower layer 12a.

The direction of the crystal axis of the first material in the metal layer 11b falls within a range of ±10° with respect to the first direction. The crystal axis of the first material is, for example, the a-axis, the b-axis, or the c-axis.

For example, when the first material is molybdenum (Mo), the direction of the crystal axis of molybdenum (Mo) in the metal layer 11b falls within a range of ±10° with respect to the first direction.

For example, when the first material is tungsten (W), the direction of the crystal axis of tungsten (W) in the metal layer 11b falls within a range of ±10° with respect to the first direction.

The crystal axis of the first material in the metal layer 11b is oriented along the first direction. The first material in the metal layer 11b is uniaxially oriented. For example, the direction of the c-axis of the first material in the metal layer 11b falls within a range of ±10° with respect to the first direction.

The angle between the direction of the crystal axis of the first material in the metal layer 11b and the first direction can be determined, for example, by comparing the arrangement direction of spots obtained by fast Fourier transform analysis of the TEM image of the cross section of the metal layer 11b with the first direction. For example, the angle between the spot arrangement direction and the first direction is measured at a plurality of locations on the cross section of the metal layer 11b. Then, for example, the average value of the measured angles is determined as the angle between the direction of the crystal axis of the first material in the metal layer 11b and the first direction.

The direction of the crystal axis of the second material in the barrier metal layer 11a falls within a range of ±10° with respect to the first direction. The crystal axis of the second material is, for example, the a-axis, the b-axis, or the c-axis.

For example, when the second material is molybdenum nitride, the direction of the crystal axis of molybdenum nitride in the barrier metal layer 11a falls within a range of ±10° with respect to the first direction.

For example, when the second material is titanium nitride, the direction of the crystal axis of titanium nitride in the barrier metal layer 11a falls within a range of ±10° with respect to the first direction.

For example, when the second material is niobium nitride, the direction of the crystal axis of niobium nitride in the barrier metal layer 11a falls within a range of ±10° with respect to the first direction.

The crystal axis of the second material in the barrier metal layer 11a is oriented along the first direction. The second material in the barrier metal layer 11a is uniaxially oriented. For example, the direction of the c-axis of the second material in the barrier metal layer 11a falls within a range of ±10° with respect to the first direction.

The angle between the direction of the crystal axis of the second material in the barrier metal layer 11a and the first direction can be determined, for example, by comparing the arrangement direction of spots obtained by fast Fourier transform analysis of the TEM image of the cross section of the barrier metal layer 11a with the first direction. For example, the angle between the spot arrangement direction and the first direction is measured at a plurality of locations on the cross section of the barrier metal layer 11a. Then, for example, the average value of the measured angles is determined as the angle between the direction of the crystal axis of the second material in the barrier metal layer 11a and the first direction.

For example, the upper layer 12b and the barrier metal layer 11a are in contact with each other. In addition, for example, the barrier metal layer 11a and the metal layer 11b are in contact with each other.

Next, a method for manufacturing the semiconductor device according to the first embodiment will be described.

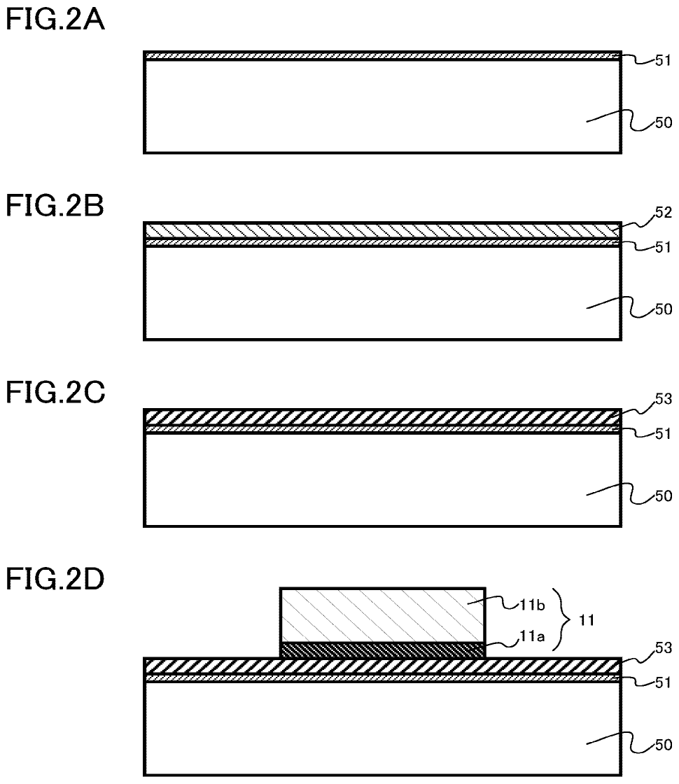

FIGS. 2A to 2D are explanatory diagrams of the method for manufacturing the semiconductor device according to the first embodiment.

First, a p-type single crystal silicon layer 50 is prepared. The single crystal silicon layer 50 is an example of a semiconductor layer.

Then, a silicon oxide film 51 is formed on the single crystal silicon layer 50 (FIG. 2A). The silicon oxide film 51 is formed, for example, by thermally oxidizing the surface of the single crystal silicon layer 50. The silicon oxide film 51 finally becomes the lower layer 12a. The thickness of the silicon oxide film 51 is, for example, equal to or more than 0.3 nm and equal to or less than 2 nm.

Then, a first aluminum nitride film 52 is formed on the silicon oxide film 51 (FIG. 2B). The thickness of the first aluminum nitride film 52 is, for example, equal to or more than 0.5 nm and less than 2.5 nm. The first aluminum nitride film 52 is formed by using, for example, an atomic layer deposition method (ALD method).

Then, the first aluminum nitride film 52 is oxidized to form a first aluminum oxide film 53 (FIG. 2C). The first aluminum nitride film 52 is oxidized, for example, at a temperature equal to or more than 900° C. and equal to or less than 1150° C.

The first aluminum nitride film 52 is oxidized, for example, in an atmosphere containing hydrogen. The first aluminum nitride film 52 is oxidized, for example, in an atmosphere containing oxygen gas and hydrogen gas. The first aluminum nitride film 52 is oxidized by using, for example, in-situ steam generation (ISSG) oxidation.

The thickness of the aluminum oxide film formed by oxidizing the aluminum nitride film is, for example, larger than the thickness of the aluminum nitride film.

The first aluminum oxide film 53 finally becomes the upper layer 12b. The lower layer 12a and the upper layer 12b serve as the gate insulating layer 12.

Then, the gate electrode layer 11 is formed on the first aluminum oxide film 53 (FIG. 2D). For example, a molybdenum nitride film and a molybdenum film are formed by using a chemical vapor deposition method (CVD method). Thereafter, the stacked molybdenum nitride film and molybdenum film are patterned using, for example, a lithography method and a reactive ion etching method (RIE method) to form the gate electrode layer 11.

Thereafter, an n-type impurity region is formed in the single crystal silicon layer 50 by using an ion implantation method. The n-type impurity region becomes the source region 10a and the drain region 10b.

By the manufacturing method described above, the MOSFET 100 shown in FIG. 1 is manufactured.

Next, the function and effect of the semiconductor device according to the first embodiment will be described.

For example, a logic device includes a scaled-down metal oxide semiconductor field effect transistor (MOSFET) in order to improve the performance of the device. The scaled-down MOSFET requires a low-resistance gate electrode layer to suppress gate delay and achieve high speed.

In the MOSFET 100 according to the first embodiment, the direction of the crystal axis of the first material in the metal layer 11b forming the gate electrode layer 11 falls within a range of ±10° with respect to the first direction. In other words, the direction of the crystal axis of the first material in the metal layer 11b is oriented along the first direction.

Since the direction of the crystal axis of the first material in the metal layer 11b is oriented, the crystallinity of the metal layer 11b is improved. For example, the grain size of the crystal of the first material in the metal layer 11b increases.

By improving the crystallinity of the metal layer 11b, the electrical resistance of the metal layer 11b is reduced as compared with, for example, a case where the first material is amorphous or a case where the grain size of the crystal of the first material is small. Therefore, the electrical resistance of gate electrode layer 11 can be reduced.

In the MOSFET 100 according to the first embodiment, the direction of the crystal axis of the second material of the barrier metal layer 11a below the metal layer 11b falls within a range of ±100 with respect to the first direction. In other words, the direction of the crystal axis of the second material in the barrier metal layer 11a is oriented along the first direction. Since the direction of the crystal axis of the second material in the barrier metal layer 11a is oriented, the direction of the crystal axis of the first material in the metal layer 11b formed on the barrier metal layer 11a is oriented.

Since the direction of the crystal axis of the second material in the barrier metal layer 11a is oriented, the crystallinity of the barrier metal layer 11a is improved. The improved crystallinity of the barrier metal layer 11a reduces the electrical resistance of the barrier metal layer 11a. Therefore, the electrical resistance of the gate electrode layer 11 can be reduced.

In addition, since the direction of the crystal axis of the second material in the barrier metal layer 11a and the direction of the crystal axis of the first material in the metal layer 11b are oriented along the same direction, the crystal continuity at the interface between the barrier metal layer 11a and the metal layer 11b is improved. Therefore, scattering of carriers at the interface between the barrier metal layer 11a and the metal layer 11b can be suppressed. As a result, the electrical resistance of gate electrode layer 11 can be reduced.

In the MOSFET 100 according to the first embodiment, the direction of the crystal axis of aluminum oxide in the upper layer 12b below the barrier metal layer 11a falls within a range of ±10° with respect to the first direction. In other words, the direction of the crystal axis of aluminum oxide in the upper layer 12b is oriented along the first direction. Since the direction of the crystal axis of aluminum oxide in the upper layer 12b is oriented, the direction of the crystal axis of the second material in the barrier metal layer 11a formed on the upper layer 12b is oriented.

By the manufacturing method according to the first embodiment described above, the direction of the crystal axis of aluminum oxide in the upper layer 12b can be oriented along the first direction. That is, by forming an aluminum oxide film by oxidizing an aluminum nitride film with a thickness less than 2.5 nm, the direction of the crystal axis of the aluminum oxide can be oriented along the first direction.

In addition, since the direction of the crystal axis of aluminum oxide in the upper layer 12b and the direction of the crystal axis of the second material in the barrier metal layer 11a are oriented along the same direction, the crystal continuity at the interface between the upper layer 12b and the barrier metal layer 11a is improved. Therefore, scattering of carriers at the interface between the upper layer 12b and the barrier metal layer 11a can be suppressed. As a result, the electrical resistance of gate electrode layer 11 can be reduced.

From the viewpoint of reducing the electrical resistance of the gate electrode layer 11, it is preferable that the direction of the crystal axis of the first material in the metal layer 11b forming the gate electrode layer 11 falls within a range of ±5° with respect to the first direction. In addition, from the viewpoint of reducing the electrical resistance of the gate electrode layer 11, it is preferable that the direction of the crystal axis of the second material in the barrier metal layer 11a forming the gate electrode layer 11 falls within a range of ±5° with respect to the first direction. In addition, from the viewpoint of reducing the electrical resistance of the gate electrode layer 11, it is preferable that the direction of the crystal axis of aluminum oxide in the upper layer 12b forming the gate insulating layer 12 falls within a range of ±5° with respect to the first direction.

In addition, the aluminum oxide contained in the upper layer 12b of the gate insulating layer 12 includes at least one crystal phase selected from a group consisting of α (alpha)-aluminum oxide and θ (theta)-aluminum oxide. Since the aluminum oxide contained in the upper layer 12b includes at least one crystal phase selected from a group consisting of α-aluminum oxide and θ-aluminum oxide, the leakage current of the upper layer 12b is reduced. The α-aluminum oxide and the θ-aluminum oxide have smaller leakage currents than other crystal phases, such as γ-aluminum oxide.

From the viewpoint of reducing the leakage current of the gate insulating layer 12, it is preferable that, among the crystal phases of aluminum oxide contained in the upper layer 12b, at least one crystal phase selected from a group consisting of α-aluminum oxide and θ-aluminum oxide is the main crystal phase. Being the main crystal phase means having a higher abundance ratio than other crystal phases.

The direction of the crystal axis of aluminum oxide in the upper layer 12b falls within a range of ±10° with respect to the first direction. That is, the aluminum oxide in the upper layer 12b is uniaxially oriented. The uniaxial orientation of the aluminum oxide in the upper layer 12b reduces the leakage current of the upper layer 12b. It is thought that the leakage current can be reduced by increasing the crystallinity of aluminum oxide in the upper layer 12b.

From the viewpoint of reducing the leakage current of the gate insulating layer 12, it is preferable that the direction of the crystal axis of aluminum oxide in the upper layer 12b falls within a range of ±5° with respect to the first direction.

In the MOSFET 100 according to the first embodiment, an aluminum oxide film formed by oxidizing a thick aluminum nitride film with a thickness equal to or more than 2.5 nm has an increased leakage current. When the thickness of the aluminum nitride film becomes equal to or more than 2.5 nm, the surface roughness after oxidation increases rapidly. The rapid increase in surface roughness is thought to be the cause of the increase in leakage current.

In the MOSFET 100 according to the first embodiment, from the viewpoint of reducing the leakage current of the gate insulating layer 12, it is preferable that the thickness of the upper layer 12b in the first direction is equal to or less than 2.0 nm.

### First Modification Example

A first modification example of the semiconductor device according to the first embodiment is different from the semiconductor device according to the first embodiment in that the thickness of the first insulating layer is more than 2.5 nm.

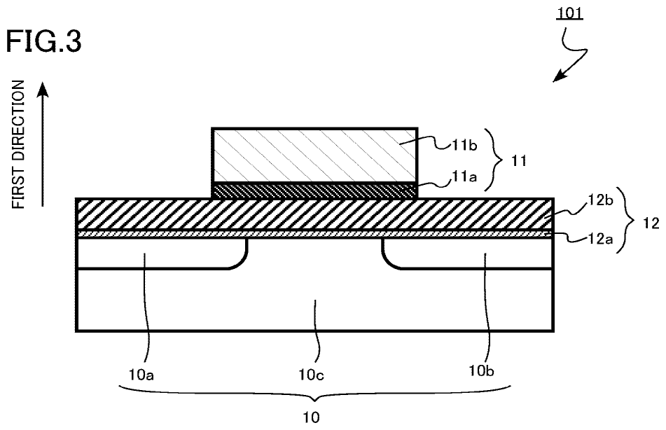

FIG. 3 is a schematic cross-sectional view of the first modification example of the semiconductor device according to the first embodiment. The first modification example of the semiconductor device according to the first embodiment is a MOSFET 101.

The thickness of an upper layer 12b of the MOSFET 101 in the first direction is, for example, more than 2.5 nm. The thickness of the upper layer 12b in the first direction is, for example, equal to or less than 30 nm.

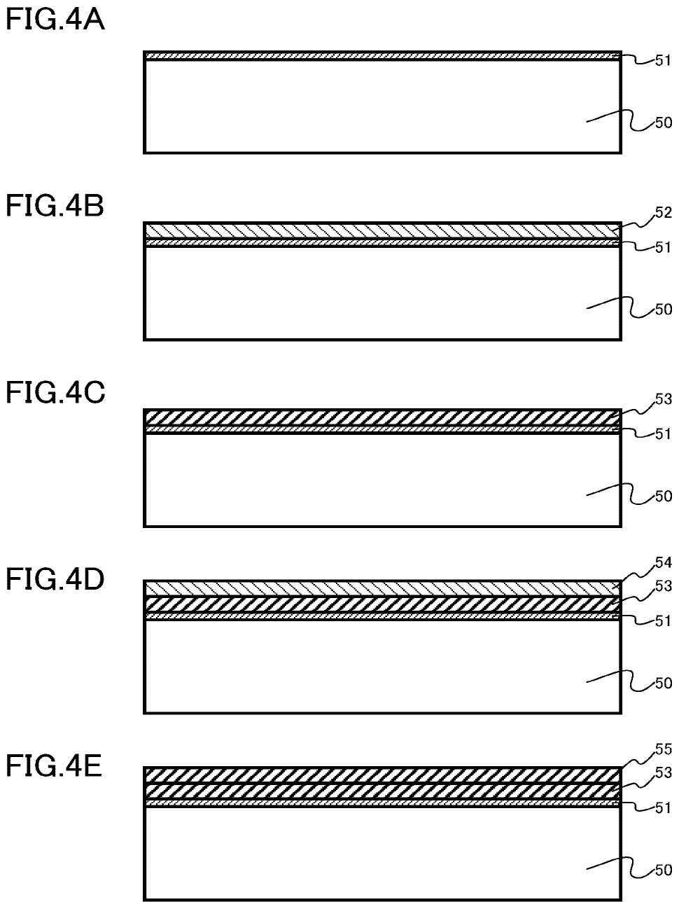

FIGS. 4A, 4B, 4C, 4D, and 4E are explanatory diagrams of a method for manufacturing the first modification example of the semiconductor device according to the first embodiment.

First, a p-type single crystal silicon layer 50 is prepared. The single crystal silicon layer 50 is an example of a semiconductor layer.

Then, a silicon oxide film 51 is formed on the single crystal silicon layer 50 (FIG. 4A). The silicon oxide film 51 is formed, for example, by thermally oxidizing the surface of the single crystal silicon layer 50. The silicon oxide film 51 finally becomes the lower layer 12a.

Then, a first aluminum nitride film 52 is formed on the silicon oxide film 51 (FIG. 4B). The thickness of the first aluminum nitride film 52 is, for example, equal to or more than 0.5 nm and less than 2.5 nm. The first aluminum nitride film 52 is formed by using, for example, an ALD method.

Then, the first aluminum nitride film 52 is oxidized to form a first aluminum oxide film 53 (FIG. 4C). The first aluminum nitride film 52 is oxidized, for example, at a temperature equal to or more than 900° C. and equal to or less than 1150° C.

The first aluminum nitride film 52 is oxidized, for example, in an atmosphere containing hydrogen. The first aluminum nitride film 52 is oxidized, for example, in an atmosphere containing oxygen gas and hydrogen gas. The first aluminum nitride film 52 is oxidized by, for example, ISSG oxidation.

The first aluminum oxide film 53 finally becomes a part of the upper layer 12b.

Then, a second aluminum nitride film 54 is formed on the first aluminum oxide film 53 (FIG. 4D). The thickness of the second aluminum nitride film 54 is, for example, equal to or more than 0.5 nm and less than 2.5 nm. The second aluminum nitride film 54 is formed by using, for example, an ALD method.

Then, the second aluminum nitride film 54 is oxidized to form a second aluminum oxide film 55 (FIG. 4E). The second aluminum nitride film 54 is oxidized, for example, at a temperature equal to or more than 900° C. and equal to or less than 1150° C.

The second aluminum nitride film 54 is oxidized, for example, in an atmosphere containing hydrogen. The second aluminum nitride film 54 is oxidized, for example, in an atmosphere containing oxygen gas and hydrogen gas. The second aluminum nitride film 54 is oxidized by, for example, ISSG oxidation.

The second aluminum oxide film 55 finally becomes a part of the upper layer 12b. The thickness of the stacked film of the first aluminum oxide film 53 and the second aluminum oxide film 55 is, for example, more than 2.5 nm. The stacked film of the first aluminum oxide film 53 and the second aluminum oxide film 55 finally becomes the gate insulating layer 12.

Then, the gate electrode layer 11 is formed on the second aluminum oxide film 55. Then, an n-type impurity region is formed in the single crystal silicon layer 50 by using an ion implantation method. The n-type impurity region becomes the source region 10a and the drain region 10b.

By the manufacturing method described above, the MOSFET 101 shown in FIG. 3 is manufactured.

In addition, after forming the second aluminum oxide film 55, it is possible to further increase the thickness of the upper layer 12b by repeating the formation of an aluminum nitride film and the oxidation of the aluminum nitride film.

According to the MOSFET 101 of the first modification example, even when the thickness of the upper layer 12b is larger than 2.5 nm, the leakage current of the gate insulating layer 12 can be reduced.

As described above, the aluminum oxide film formed by oxidizing a thick aluminum nitride film with a thickness equal to or more than 2.5 nm has an increased leakage current. According to the method for manufacturing the first modification example of the first embodiment, it is possible to form an aluminum oxide film with a thickness equal to or more than 2.5 nm and reduced leakage current by repeating the formation and oxidation of an aluminum nitride film with a thickness less than 2.5 nm.

### Second Modification Example

A second modification example of the semiconductor device according to the first embodiment is different from the semiconductor device according to the first embodiment in that a third insulating layer is further provided that is provided between the first insulating layer and the gate electrode layer and contains a third material having a higher dielectric constant than silicon oxide and different from aluminum oxide.

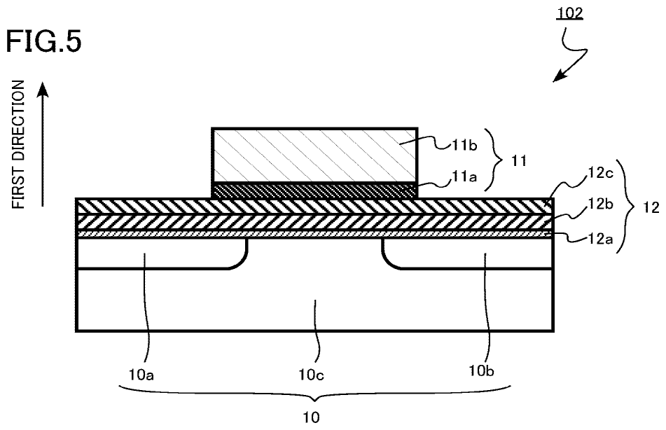

FIG. 5 is a schematic cross-sectional view of the second modification example of the semiconductor device according to the first embodiment. The second modification example of the semiconductor device according to the first embodiment is a MOSFET 102.

A gate insulating layer 12 is provided between a semiconductor layer 10 and a gate electrode layer 11. The gate insulating layer 12 includes a lower layer 12a, an upper layer 12b, and a high dielectric constant layer 12c. The lower layer 12a is an example of a second insulating layer. The upper layer 12b is an example of a first insulating layer. The high dielectric constant layer 12c is an example of a third insulating layer.

The high dielectric constant layer 12c is provided between the upper layer 12b and the gate electrode layer 11. The high dielectric constant layer 12c is provided between the upper layer 12b and the barrier metal layer 11a. The high dielectric constant layer 12c is in contact with, for example, the upper layer 12b and the barrier metal layer 11a.

The high dielectric constant layer 12c is an insulating layer. The high dielectric constant layer 12c contains a third material having a higher dielectric constant than silicon oxide and different from aluminum oxide.

The third material is the main component of the high dielectric constant layer 12c. The high dielectric constant layer 12c is formed of, for example, a third material.

The third material is an insulator. The third material is, for example, at least one material selected from a group consisting of hafnium oxide, zirconium oxide, tantalum oxide, lanthanum oxide, and cerium oxide. The high dielectric constant layer 12c is, for example, a hafnium oxide layer, a zirconium oxide layer, a tantalum oxide layer, a lanthanum oxide layer, or a cerium oxide layer.

The direction of the crystal axis of the third material in the high dielectric constant layer 12c falls within a range of ±10° with respect to the first direction. The crystal axis of the third material is, for example, the a-axis, the b-axis, or the c-axis.

The crystal axis of the third material in the high dielectric constant layer 12c is oriented along the first direction. The third material in the high dielectric constant layer 12c is uniaxially oriented. For example, the direction of the c-axis of the third material in the high dielectric constant layer 12c falls within a range of ±10° with respect to the first direction.

The angle between the direction of the crystal axis of the third material in the high dielectric constant layer 12c and the first direction can be determined, for example, by comparing the arrangement direction of spots obtained by fast Fourier transform analysis of the TEM image of the cross section of the high dielectric constant layer 12c with the first direction.

The thickness of the high dielectric constant layer 12c in the first direction from the semiconductor layer 10 toward the gate electrode layer 11 is, for example, equal to or more than 0.5 nm and equal to or less than 2.5 nm.

According to the MOSFET 102 of the second modification example, since the gate insulating layer 12 includes the high dielectric constant layer 12c, the controllability of the operation of the MOSFET 102 is improved, for example.

As described above, according to the first embodiment and its modification examples, it is possible to provide a semiconductor device including a low-resistance gate electrode layer.

### Second Embodiment

A semiconductor memory device according to a second embodiment includes: a semiconductor layer extending in a first direction; a gate electrode layer including a first conductive layer containing a first material and a second conductive layer provided between the first conductive layer and the semiconductor layer and containing a second material different from the first material; a charge storage layer provided between the semiconductor layer and the gate electrode layer; a first insulating layer provided between the charge storage layer and the gate electrode layer and containing aluminum oxide, the aluminum oxide including at least one crystal phase selected from a group consisting of α (alpha)-aluminum oxide and θ (theta)-aluminum oxide; and a second insulating layer provided between the charge storage layer and the semiconductor layer. Then, the direction of the crystal axis of the aluminum oxide in the first insulating layer falls within a range of ±10° with respect to a second direction from the semiconductor layer toward the gate electrode layer. The direction of the crystal axis of the first material in the first conductive layer falls within a range of ±10° with respect to the second direction. The direction of a crystal axis of the second material in the second conductive layer falls within a range of ±10° with respect to the second direction.

The semiconductor memory device according to the second embodiment is a three-dimensional NAND flash memory. The memory cell of the semiconductor memory device according to the second embodiment is a so-called metal-oxide-nitride-oxide-semiconductor type (MONOS type) memory cell.

In addition, in the memory cell of the semiconductor memory device according to the second embodiment, an insulating layer containing aluminum oxide, similar to the first insulating layer of the semiconductor device according to the first embodiment, is applied to a block insulating layer. In addition, the block insulating layer of the memory cell of the semiconductor memory device according to the second embodiment is formed by using the same manufacturing method as the method for manufacturing the semiconductor device according to the first embodiment. Hereinafter, the description of a part of the content overlapping the first embodiment may be omitted.

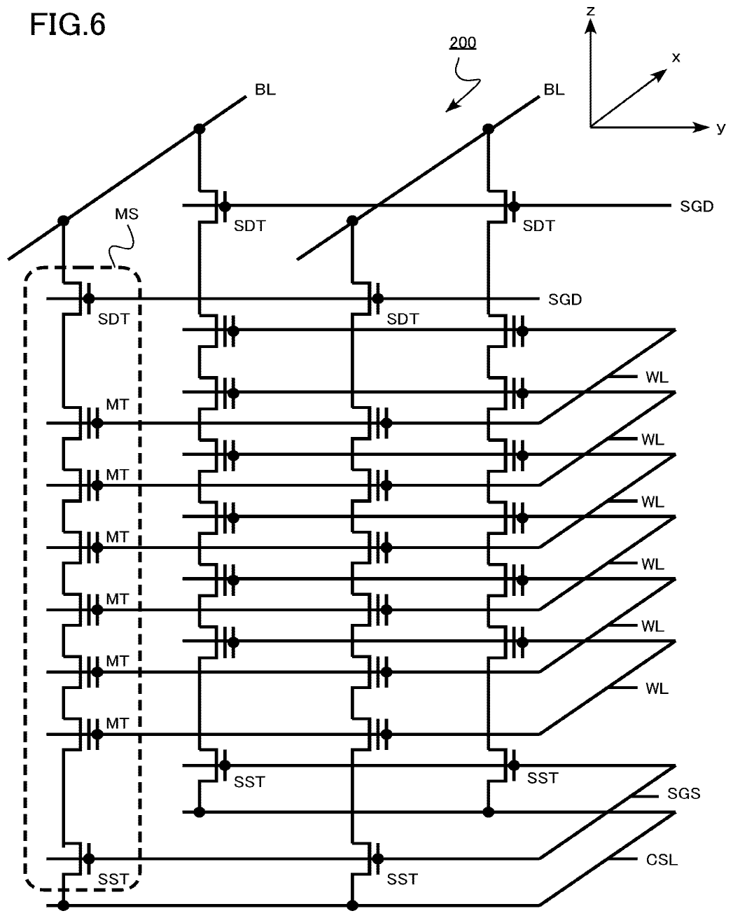

FIG. 6 is a circuit diagram of a memory cell array of the semiconductor memory device according to the second embodiment.

As shown in FIG. 6, a memory cell array 200 of a three-dimensional NAND flash memory according to the second embodiment includes a plurality of word lines WL, a common source line CSL, a source selection gate line SGS, a plurality of drain selection gate lines SGD, a plurality of bit lines BL, and a plurality of memory strings MS.

The plurality of word lines WL are arranged so as to be spaced from each other in the z direction. The plurality of word lines WL are arranged so as to be stacked in the z direction. The plurality of memory strings MS extend in the z direction. The plurality of bit lines BL extend in the x direction, for example.

Hereinafter, the x direction is defined as a third direction, the y direction is defined as a second direction, and the z direction is defined as a first direction. The x direction, the y direction, and the z direction cross each other. For example, the x direction, the y direction, and the z direction are perpendicular to each other.

As shown in FIG. 6, the memory string MS includes a source selection transistor SST, a plurality of memory cells, and a drain selection transistor SDT connected in series to each other between the common source line CSL and the bit line BL. By selecting one bit line BL and one drain selection gate line SGD, one memory string MS is selected. Then, by selecting one word line WL, one memory cell can be selected. The word line WL is a gate electrode of a memory cell transistor MT forming the memory cell.

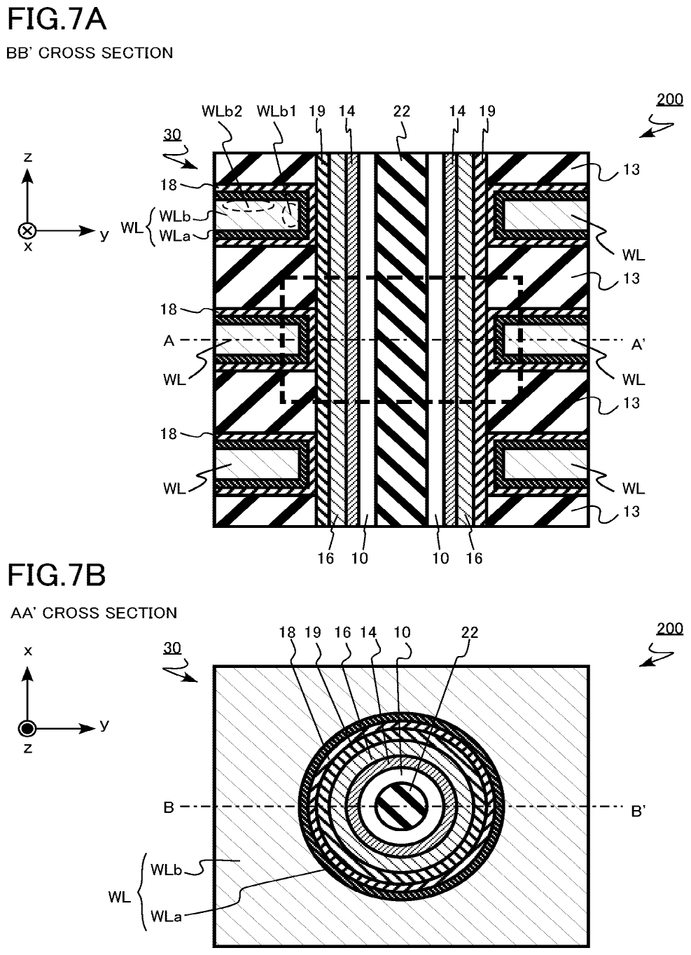

FIGS. 7A and 7B are schematic cross-sectional views of a memory cell array of the semiconductor memory device according to the second embodiment. FIGS. 7A and 7B show cross sections of a plurality of memory cells in one memory string MS in the memory cell array 200 shown in FIG. 6.

FIG. 7A is a yz cross-sectional view of the memory cell array 200. FIG. 7A is a cross-sectional view taken along the line BB′ of FIG. 7B. FIG. 7B is an xy cross-sectional view of the memory cell array 200. FIG. 7B is a cross-sectional view taken along the line AA′ of FIG. 7A. In FIG. 7A, the region surrounded by the broken line is one memory cell.

As shown in FIGS. 7A and 7B, the memory cell array 200 includes a word line WL, a semiconductor layer 10, an interlayer insulating layer 13, a tunnel insulating layer 14, a charge storage layer 16, a first block insulating layer 18, a second block insulating layer 19, and a core insulating region 22. A plurality of word lines WL and a plurality of interlayer insulating layers 13 form a stacked body 30.

The word line WL is an example of a gate electrode layer. The interlayer insulating layer 13 is an example of a fifth insulating layer. The tunnel insulating layer 14 is an example of a second insulating layer. The first block insulating layer 18 is an example of a first insulating layer. The second block insulating layer 19 is an example of a fourth insulating layer.

The word line WL includes a barrier metal layer WLa and a metal layer WLb. The barrier metal layer WLa is an example of a second conductive layer. The metal layer WLb is an example of a first conductive layer.

The memory cell array 200 is provided, for example, on a semiconductor substrate (not shown). The semiconductor substrate has, for example, a surface parallel to the x direction and the y direction.

The word line WL and the interlayer insulating layer 13 are alternately stacked in the z direction on the semiconductor substrate. The word lines WL are repeatedly arranged in the z direction so as to be spaced from each other. A plurality of word lines WL and a plurality of interlayer insulating layers 13 form the stacked body 30. The word line WL functions as a control electrode of the memory cell transistor MT.

The word line WL surrounds the semiconductor layer 10. The word line WL surrounds the charge storage layer 16. The word line WL surrounds the first block insulating layer 18 and the second block insulating layer 19.

The word line WL is, for example, a plate-shaped conductor. The word line WL includes the barrier metal layer WLa and the metal layer WLb.

The barrier metal layer WLa is provided between the metal layer WLb and the semiconductor layer 10. The barrier metal layer WLa is provided between the metal layer 11b and the first block insulating layer 18.

The metal layer WLb contains a first material. The barrier metal layer WLa contains the second material. The first material and the second material are different.

The first material is the main component of the metal layer WLb. The metal layer WLb is formed of, for example, a first material.

The first material is, for example, a metal or a metal compound. The first material is, for example, at least one material selected from a group consisting of molybdenum (Mo) and tungsten (W). The metal layer WLb is, for example, a molybdenum layer or a tungsten layer.

The second material is the main component of the barrier metal layer WLa. The barrier metal layer WLa is formed of, for example, a second material.

The second material is, for example, a metal or a metal compound. The second material is, for example, at least one material selected from a group consisting of molybdenum nitride, titanium nitride, and niobium nitride. The barrier metal layer WLa is, for example, a molybdenum nitride layer, a titanium nitride layer, or a niobium nitride layer.

The thickness of the word line WL in the z direction is, for example, equal to or more than 5 nm and equal to or less than 20 nm.

The interlayer insulating layer 13 separates the word lines WL from each other. The interlayer insulating layer 13 electrically separates the word lines WL from each other.

The interlayer insulating layer 13 is, for example, an oxide, an oxynitride, or a nitride. The interlayer insulating layer 13 contains, for example, silicon (Si) and oxygen (O). The interlayer insulating layer 13 is, for example, a silicon oxide. The thickness of the interlayer insulating layer 13 in the z direction is, for example, equal to or more than 5 nm and equal to or less than 20 nm.

The semiconductor layer 10 is provided in the stacked body 30. The semiconductor layer 10 extends in the z direction. The semiconductor layer 10 extends, for example, in a direction perpendicular to the surface of the semiconductor substrate.

The semiconductor layer 10 is provided so as to penetrate the stacked body 30. The semiconductor layer 10 is surrounded by a plurality of word lines WL. The semiconductor layer 10 has, for example, a cylindrical shape. The semiconductor layer 10 functions as a channel of the memory cell transistor MT.

The semiconductor layer 10 is, for example, a polycrystalline semiconductor. The semiconductor layer 10 is, for example, polycrystalline silicon.

The tunnel insulating layer 14 is provided between the semiconductor layer 10 and the word line WL. The tunnel insulating layer 14 is provided between the semiconductor layer 10 and at least one of the plurality of word lines WL. The tunnel insulating layer 14 is provided between the semiconductor layer 10 and the charge storage layer 16. The tunnel insulating layer 14 has a function of allowing a charge to pass according to a voltage applied between the word line WL and the semiconductor layer 10.

The tunnel insulating layer 14 contains, for example, silicon (Si), nitrogen (N), and oxygen (O). The tunnel insulating layer 14 contains, for example, silicon oxide, silicon nitride, or silicon oxynitride. The thickness of the tunnel insulating layer 14 is, for example, equal to or more than 3 nm and equal to or less than 8 nm.

The charge storage layer 16 is provided between the tunnel insulating layer 14 and the first block insulating layer 18. The charge storage layer 16 is provided between the tunnel insulating layer 14 and the second block insulating layer 19.

The charge storage layer 16 has a function of trapping and storing a charge. The charge is, for example, an electron. The threshold voltage of the memory cell transistor MT changes according to the amount of charge stored in the charge storage layer 16. By using the threshold voltage change, one memory cell can store data.

For example, when the threshold voltage of the memory cell transistor MT changes, the voltage at which the memory cell transistor MT is turned on changes. For example, if a state in which the threshold voltage is high is defined as data “0” and a state in which the threshold voltage is low is defined as data “1”, the memory cell can store 1-bit data of “0” and “1”.

The charge storage layer 16 is, for example, an insulating layer. The charge storage layer 16 contains, for example, silicon (Si) and nitrogen (N). The charge storage layer 16 contains, for example, silicon nitride. The thickness of the charge storage layer 16 is, for example, equal to or more than 3 nm and equal to or less than 10 nm.

The first block insulating layer 18 and the second block insulating layer 19 are provided between the tunnel insulating layer 14 and the word line WL. The first block insulating layer 18 and the second block insulating layer 19 are provided between the charge storage layer 16 and the word line WL. The first block insulating layer 18 and the second block insulating layer 19 have a function of blocking the current flowing between the charge storage layer 16 and the word line WL.

The first block insulating layer 18 is provided between the charge storage layer 16 and the word line WL. The first block insulating layer 18 is provided between the second block insulating layer 19 and the word line WL.

The interlayer insulating layer 13 is provided in the z direction of the word line WL. The word line WL and the interlayer insulating layer 13 are arranged in the z direction. In the z direction, the first block insulating layer 18 is provided between the word line WL and the interlayer insulating layer 13.

As shown in FIG. 7B, the first block insulating layer 18 surrounds the semiconductor layer 10. The first block insulating layer 18 surrounds the charge storage layer 16. As shown in FIG. 7B, the first block insulating layer 18 has an annular shape in a cross section perpendicular to the z direction.

The first block insulating layer 18 is an insulating layer. The first block insulating layer 18 contains aluminum oxide. The aluminum oxide is the main component of the first block insulating layer 18. The first block insulating layer 18 is, for example, an aluminum oxide layer.

The aluminum oxide contained in the first block insulating layer 18 includes at least one crystal phase selected from a group consisting of α (alpha)-aluminum oxide and θ (theta)-aluminum oxide.

The α-aluminum oxide has a hexagonal crystal structure. The θ-aluminum oxide has a monoclinic crystal structure.

The aluminum oxide contained in the first block insulating layer 18 may contain γ (gamma)-aluminum oxide. The γ-aluminum oxide has a cubic crystal structure.

The direction of the crystal axis of aluminum oxide in the first block insulating layer 18 disposed between the word line WL and the second block insulating layer 19 falls within a range of ±10° with respect to the y direction from the semiconductor layer 10 toward the word line WL. The crystal axis of aluminum oxide is, for example, the a-axis, the b-axis, or the c-axis. The y direction is, for example, a direction perpendicular to the interface between the tunnel insulating layer 14 and the semiconductor layer 10. The y direction is the thickness direction of the first block insulating layer 18 disposed between the word line WL and the second block insulating layer 19.

The crystal axis of aluminum oxide in the first block insulating layer 18 disposed between the word line WL and the second block insulating layer 19 is oriented along the y direction. The aluminum oxide in the first block insulating layer 18 is uniaxially oriented. The direction of the c-axis of the aluminum oxide in the first block insulating layer 18 falls within a range of ±10° with respect to the y direction, for example.

The direction of the crystal axis of aluminum oxide in the first block insulating layer 18 disposed between the word line WL and the interlayer insulating layer 13 falls within a range of ±10° with respect to the z direction in which the semiconductor layer 10 extends. The crystal axis of aluminum oxide is, for example, the a-axis, the b-axis, or the c-axis. The z direction is, for example, a direction perpendicular to the interface between the first block insulating layer 18 and the interlayer insulating layer 13. The z direction is the thickness direction of the first block insulating layer 18 disposed between the word line WL and the interlayer insulating layer 13.

The crystal axis of aluminum oxide in the first block insulating layer 18 disposed between the word line WL and the interlayer insulating layer 13 is oriented along the z direction. The aluminum oxide in the first block insulating layer 18 is uniaxially oriented. The direction of the c-axis of aluminum oxide in the first block insulating layer 18 falls within a range of ±10° with respect to the z direction, for example.

The angle between the direction of the crystal axis of aluminum oxide in the first block insulating layer 18 and the y direction or the z direction can be determined, for example, by comparing the arrangement direction of spots obtained by fast Fourier transform analysis of the TEM image of the cross section of the first block insulating layer 18 with the y direction or the z direction. For example, the angle between the spot arrangement direction and the y direction or the z direction is measured at a plurality of locations on the cross section of the first block insulating layer 18. Then, for example, the average value of the measured angles is calculated as the angle between the direction of the crystal axis of aluminum oxide in the first block insulating layer 18 and the y direction or as the angle between the direction of the crystal axis of aluminum oxide in the first block insulating layer 18 and the z direction.

For example, in a cross section perpendicular to the z direction as shown in FIG. 7B, the first block insulating layer 18 has an annular shape. For example, in a cross section perpendicular to the z direction, the direction of the crystal axis of aluminum oxide in the first block insulating layer 18 is radially oriented from the inside to the outside of the first block insulating layer 18. In addition, for example, in a cross section perpendicular to the z direction, the direction of the crystal axis of the first material in the metal layer WLb and the direction of the crystal axis of the second material in the barrier metal layer WLa are radially oriented from the inside to the outside of the first block insulating layer 18.

The direction of the crystal axis of aluminum oxide in the first block insulating layer 18 falls within a range of ±10° with respect to the thickness direction of the first block insulating layer 18.

The thickness of the first block insulating layer 18 in the y direction from the semiconductor layer 10 toward the word line WL is, for example, equal to or more than 0.5 nm and equal to or less than 2.5 nm.

The direction of the crystal axis of the second material in the barrier metal layer WLa disposed between the metal layer WLb and the second block insulating layer 19 falls within a range of ±10° with respect to the y direction. The crystal axis of the second material is, for example, the a-axis, the b-axis, or the c-axis.

The crystal axis of the second material in the barrier metal layer WLa disposed between the metal layer WLb and the second block insulating layer 19 is oriented along the y direction. The second material in the barrier metal layer WLa is uniaxially oriented. For example, the direction of the c-axis of the second material in the barrier metal layer WLa falls within a range of ±10° with respect to the y direction.

The direction of the crystal axis of the second material in the barrier metal layer WLa disposed between the metal layer WLb and the interlayer insulating layer 13 falls within a range of ±10° with respect to the z direction. The crystal axis of the second material is, for example, the a-axis, the b-axis, or the c-axis.

The crystal axis of the second material in the barrier metal layer WLa disposed between the metal layer WLb and the interlayer insulating layer 13 is oriented along the z direction. The second material in the barrier metal layer WLa is uniaxially oriented. For example, the direction of the c-axis of the second material in the barrier metal layer WLa falls within a range of ±10° with respect to the z direction.

The orientation direction of the crystal axis of the second material in the barrier metal layer WLa changes within the barrier metal layer WLa. For example, the crystal axis of the second material in a specific portion of the barrier metal layer WLa is oriented along a direction perpendicular to the interface between the specific portion and the first block insulating layer 18 in contact with the specific portion. For example, the direction of the crystal axis of the second material in the barrier metal layer WLa falls within a range of ±10° with respect to the thickness direction of the barrier metal layer WLa.

The angle between the direction of the crystal axis of the second material in the barrier metal layer WLa and the y direction or the z direction can be determined, for example, by comparing the arrangement direction of spots obtained by fast Fourier transform analysis of the TEM image of the cross section of the barrier metal layer WLa with the y direction or the z direction. For example, the angle between the spot arrangement direction and the y direction or the z direction is measured at a plurality of locations on the cross section of the barrier metal layer WLa. Then, for example, the average value of the measured angles is determined as the angle between the direction of the crystal axis of the second material in the barrier metal layer WLa and the y direction or as the angle between the direction of the crystal axis of the second material in the barrier metal layer WLa and the z direction.

For example, the first block insulating layer 18 and the barrier metal layer WLa are in contact with each other. In addition, for example, the barrier metal layer WLa and the metal layer WLb are in contact with each other.

A first portion WLb1 of the metal layer WLb is in contact with the barrier metal layer WLa in the y direction. The barrier metal layer WLa is provided between the first portion WLb1 and the second block insulating layer 19. The direction of the crystal axis of the first material in the first portion WLb1 falls within a range of ±10° with respect to the y direction. The crystal axis of the first material is, for example, the a-axis, the b-axis, or the c-axis.

The crystal axis of the first material in the first portion WLb1 of the metal layer WLb is oriented along the y direction. The first material in the first portion WLb1 is uniaxially oriented. For example, the direction of the c-axis of the first material in the first portion WLb1 falls within a range of ±10° with respect to the y direction.

A second portion WLb2 of the metal layer WLb is in contact with the barrier metal layer WLa in the z direction. The barrier metal layer WLa is provided between the second portion WLb2 and the interlayer insulating layer 13. The direction of the crystal axis of the first material in the second portion WLb2 falls within a range of ±10° with respect to the z direction. The crystal axis of the first material is, for example, the a-axis, the b-axis, or the c-axis.

The crystal axis of the first material in the second portion WLb2 of the metal layer WLb is oriented along the z direction. The first material in the second portion WLb2 is uniaxially oriented. For example, the direction of the c-axis of the first material in the second portion WLb2 falls within a range of ±10° with respect to the z direction.

The orientation direction of the crystal axis of the first material in the metal layer WLb changes within the metal layer WLb. For example, the crystal axis of the first material in a specific portion of the metal layer WLb is oriented along a direction perpendicular to the interface between the specific portion and the barrier metal layer WLa in contact with the specific portion. For example, the direction of the crystal axis of the first material in a specific portion of the metal layer WLb falls within a range of ±10° with respect to a direction perpendicular to the interface between the specific portion and the barrier metal layer WLa in contact with the specific portion.

The angle between the direction of the crystal axis of the first material in the metal layer WLb and the y direction or the z direction can be determined, for example, by comparing the arrangement direction of spots obtained by fast Fourier transform analysis of the TEM image of the cross section of the metal layer WLb with the y direction or the z direction. For example, the angle between the spot arrangement direction and the y direction or the z direction is measured at a plurality of locations on the cross section of the metal layer WLb. Then, for example, the average value of the measured angles is determined as the angle between the direction of the crystal axis of the first material in the metal layer WLb and the y direction or as the angle between the direction of the crystal axis of the first material in the metal layer WLb and the z direction.

The second block insulating layer 19 is provided between the charge storage layer 16 and the first block insulating layer 18. The second block insulating layer 19 is provided between the interlayer insulating layer 13 and the semiconductor layer 10. The second block insulating layer 19 is provided between the interlayer insulating layer 13 and the charge storage layer 16.

The second block insulating layer 19 is an insulating layer. The second block insulating layer 19 contains silicon (Si) and oxygen (O), for example. The second block insulating layer 19 contains silicon oxide, for example. The second block insulating layer 19 is, for example, a silicon oxide layer.

The thickness of the second block insulating layer 19 in the y direction is, for example, equal to or more than 3 nm and equal to or less than 8 nm.

The core insulating region 22 is provided within the stacked body 30. The core insulating region 22 extends in the z direction. The core insulating region 22 is provided so as to penetrate the stacked body 30. The core insulating region 22 is surrounded by the semiconductor layer 10. The core insulating region 22 is surrounded by a plurality of word lines WL. The core insulating region 22 is columnar. The core insulating region 22 is, for example, cylindrical.

The core insulating region 22 is, for example, an oxide, an oxynitride, or a nitride. The core insulating region 22 contains, for example, silicon (Si) and oxygen (O). The core insulating region 22 is, for example, a silicon oxide.

In addition, the core insulating region 22 may be omitted. When the core insulating region 22 is omitted, the semiconductor layer 10 has a cylindrical shape, for example.

Next, an example of a method for manufacturing the semiconductor memory device according to the second embodiment will be described.

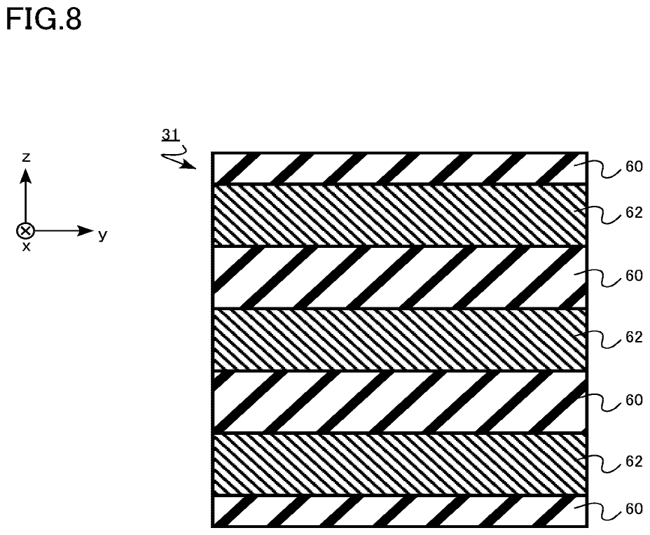

FIGS. 8 to 16 are schematic cross-sectional views showing an example of the method for manufacturing the semiconductor memory device according to the second embodiment. FIGS. 8 to 16 each show a cross section corresponding to FIG. 7A. FIGS. 8 to 16 are diagrams showing an example of a method for manufacturing the memory cell array 200 of the semiconductor memory device.

First, a silicon oxide layer 60 and a silicon nitride layer 62 are alternately stacked on a semiconductor substrate (not shown) (FIG. 8). A stacked structure 31 in which a plurality of silicon oxide layers 60 and a plurality of silicon nitride layers 62 are alternately stacked in the z direction is formed. A part of the stacked structure 31 finally becomes a part of the stacked body 30.

The silicon oxide layer 60 and the silicon nitride layer 62 are formed by using, for example, a CVD method. A part of the silicon oxide layer 60 finally becomes the interlayer insulating layer 13.

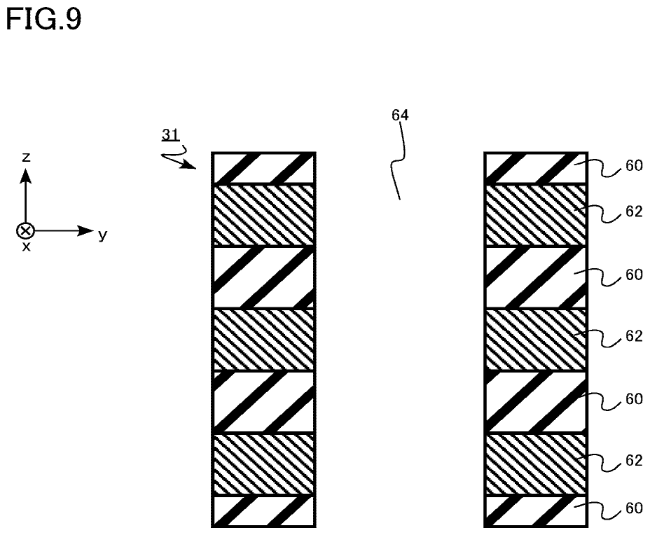

Then, a memory hole 64 is formed in the silicon oxide layer 60 and the silicon nitride layer 62 (FIG. 9). The memory hole 64 penetrates the stacked structure 31 and extends in the z direction. The memory hole 64 is formed by using, for example, a lithography method and a RIE method.

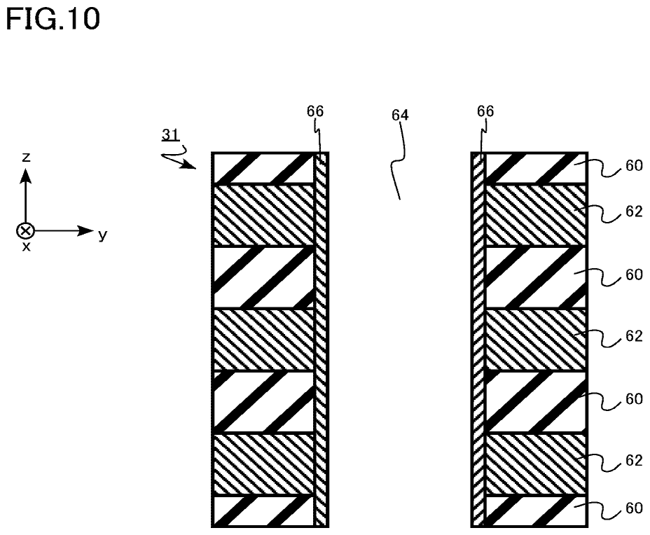

Then, a silicon oxide film 66 is formed on the inner wall of the memory hole 64 (FIG. 10). The silicon oxide film 66 is formed by using, for example, a CVD method. The silicon oxide film 66 finally becomes the second block insulating layer 19.

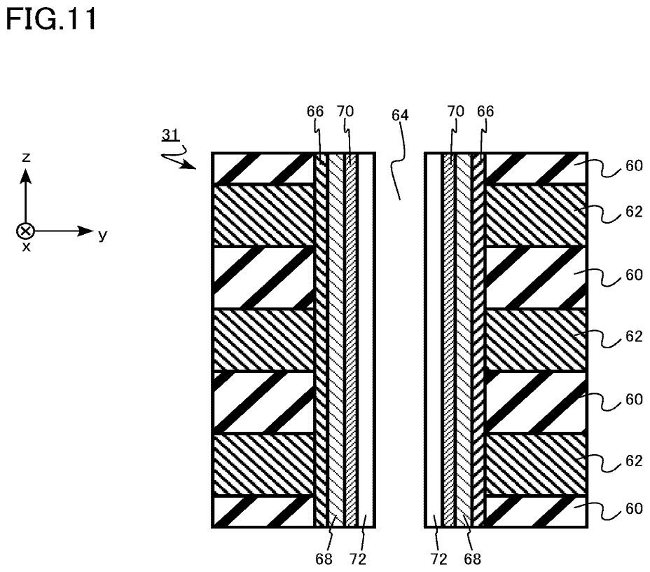

Then, a silicon nitride film 68 is formed on the silicon oxide film 66 (FIG. 11). The silicon nitride film 68 is formed by using, for example, an ALD method. The silicon nitride film 68 finally becomes the charge storage layer 16.

Then, a stacked insulating film 70 is formed on the silicon nitride film 68 (FIG. 11). The stacked insulating film 70 is, for example, a stacked film of a silicon oxide film, a silicon nitride film, and a silicon oxide film.

The stacked insulating film 70 is formed by using, for example, a CVD method. The stacked insulating film 70 finally becomes the tunnel insulating layer 14.

Then, a polycrystalline silicon film 72 is formed on the stacked insulating film 70 (FIG. 11). The polycrystalline silicon film 72 is formed by using, for example, a CVD method. The polycrystalline silicon film 72 finally becomes the semiconductor layer 10.

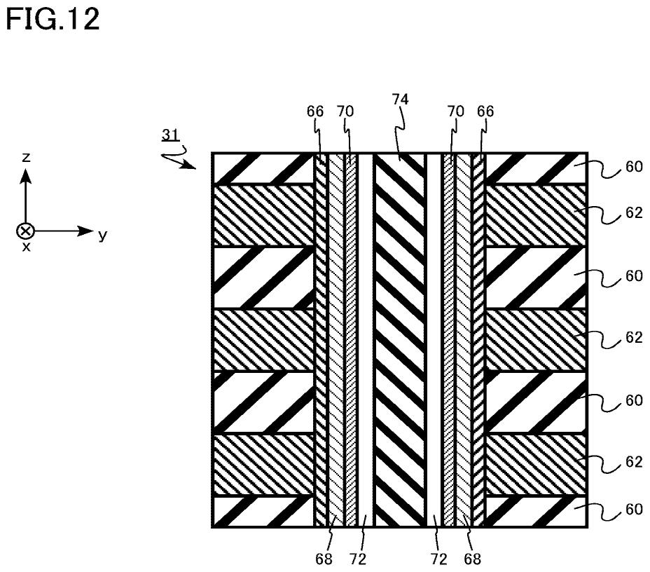

Then, a silicon oxide film 74 is buried in the memory hole 64 (FIG. 12). The silicon oxide film 74 is formed on the polycrystalline silicon film 72. The silicon oxide film 74 is formed by using, for example, a CVD method. The silicon oxide film 74 finally becomes the core insulating region 22.

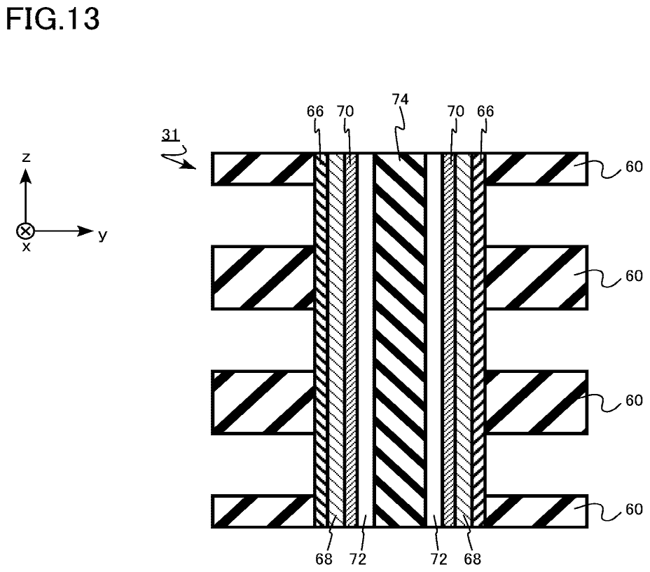

Then, the silicon nitride layer 62 is selectively removed by wet etching using a groove for etching (not shown) (FIG. 13). For wet etching, for example, a phosphoric acid solution is used. The silicon nitride layer 62 is etched selectively with respect to the silicon oxide layer 60 and the silicon oxide film 66.

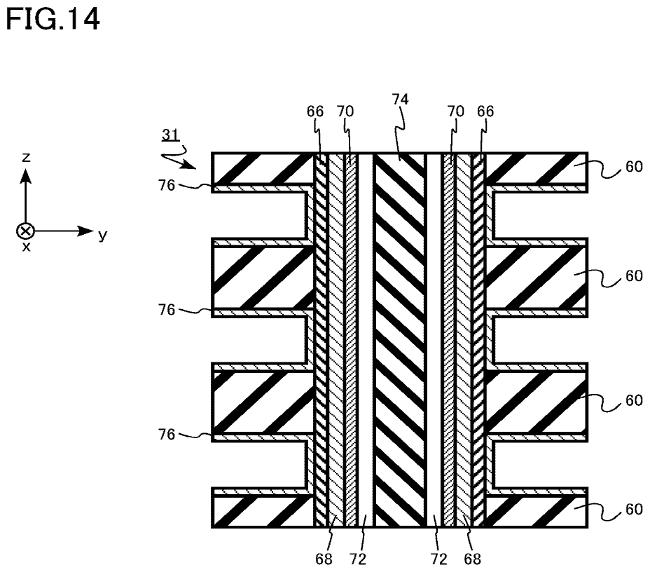

Then, an aluminum nitride film 76 is formed in a region where the silicon nitride layer 62 has been removed (FIG. 14). The thickness of the aluminum nitride film 76 is, for example, equal to or more than 0.5 nm and less than 2.5 nm. The aluminum nitride film 76 is formed by using, for example, an ALD method.

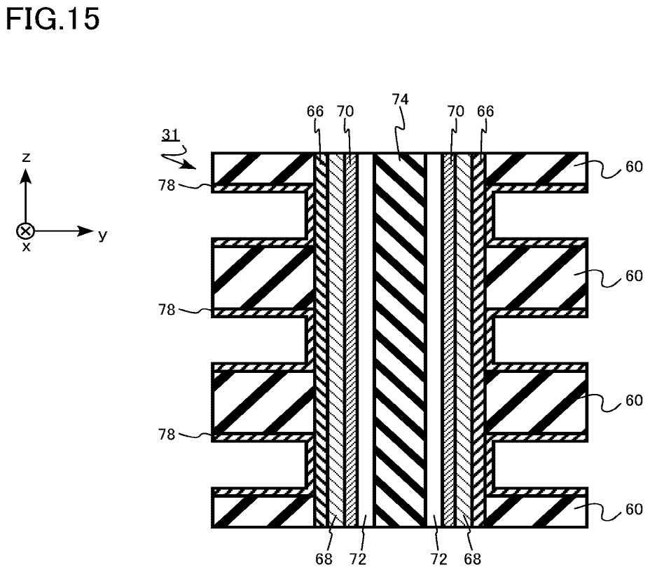

Then, the aluminum nitride film 76 is oxidized to form an aluminum oxide film 78 (FIG. 15). The aluminum nitride film 76 is oxidized, for example, at a temperature equal to or more than 900° C. and equal to or less than 1150° C.

The aluminum nitride film 76 is oxidized, for example, in an atmosphere containing hydrogen. The aluminum nitride film 76 is oxidized, for example, in an atmosphere containing oxygen gas and hydrogen gas. The aluminum nitride film 76 is oxidized by, for example, ISSG oxidation.

The aluminum oxide film 78 finally becomes the first block insulating layer 18.

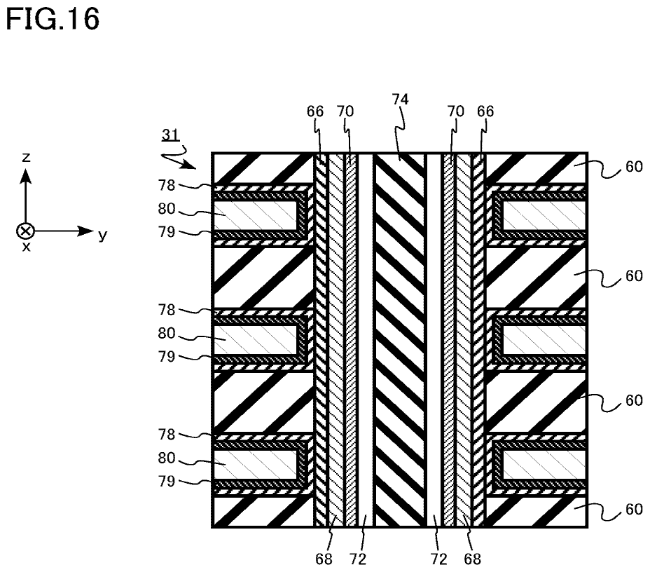

Then, a molybdenum nitride film 79 and a molybdenum film 80 are formed on the aluminum oxide film 78 (FIG. 16). The molybdenum nitride film 79 and the molybdenum film 80 are formed by using, for example, a CVD method.

The molybdenum nitride film 79 finally becomes the barrier metal layer WLa. In addition, the molybdenum film 80 finally becomes the metal layer WLb.

By the manufacturing method described above, the memory cell array 200 of the semiconductor memory device according to the second embodiment shown in FIGS. 7A and 7B is manufactured.

Next, the function and effect of the semiconductor memory device according to the second embodiment will be described.

A three-dimensional NAND flash memory in which memory cells are three-dimensionally arranged realizes a high degree of integration and a low cost. In the three-dimensional NAND flash memory, for example, a memory hole penetrating a stacked body is formed in the stacked body in which a plurality of insulating layers and a plurality of gate electrode layers are alternately stacked. By forming a charge storage layer and a semiconductor layer in the memory hole, a memory string in which a plurality of memory cells are connected in series to each other is formed. In the three-dimensional NAND flash memory with scaled-down memory cells, a low-resistance gate electrode layer (word line) is required to suppress gate delay and achieve high speed.

In the memory cell array 200 of the three-dimensional NAND flash memory according to the second embodiment, the direction of the crystal axis of the first material in the metal layer WLb forming the word line WL falls within a range of ±10° with respect to the y direction or the z direction. In other words, the direction of the crystal axis of the first material in the metal layer WLb is oriented along the y direction or the z direction.

Since the direction of the crystal axis of the first material in the metal layer WLb is oriented, the crystallinity of the metal layer WLb is improved. For example, the grain size of the crystal of the first material in the metal layer WLb increases.

By improving the crystallinity of the metal layer WLb, the electrical resistance of the metal layer WLb is reduced as compared with, for example, a case where the first material is amorphous or a case where the grain size of the crystal of the first material is small. As a result, the electrical resistance of the word line WL can be reduced.

In the memory cell array 200 of the three-dimensional NAND flash memory according to the second embodiment, the direction of the crystal axis of the second material in the barrier metal layer WLa below the metal layer WLb falls within a range of ±10° with respect to the y direction or the z direction. In other words, the direction of the crystal axis of the second material in the barrier metal layer WLa is oriented along the y direction or the z direction. Since the direction of the crystal axis of the second material in the barrier metal layer WLa is oriented, the direction of the crystal axis of the first material in the metal layer WLb formed on the barrier metal layer WLa is oriented.

Since the direction of the crystal axis of the second material in the barrier metal layer WLa is oriented, the crystallinity of the barrier metal layer WLa is improved. The improved crystallinity of the barrier metal layer WLa reduces the electrical resistance of the barrier metal layer WLa. As a result, the electrical resistance of the word line WL can be reduced.

In addition, since the direction of the crystal axis of the second material in the barrier metal layer WLa and the direction of the crystal axis of the first material in the metal layer WLb are oriented along the same direction, the crystal continuity at the interface between the barrier metal layer WLa and the metal layer WLb is improved. Therefore, scattering of carriers at the interface between the barrier metal layer WLa and the metal layer WLb can be suppressed. As a result, the electrical resistance of the word line WL can be reduced.

In the memory cell array 200 of the three-dimensional NAND flash memory according to the second embodiment, the direction of the crystal axis of aluminum oxide in the first block insulating layer 18 below the barrier metal layer WLa falls within a range of ±10° with respect to the y direction or the z direction. In other words, the direction of the crystal axis of aluminum oxide in the first block insulating layer 18 is oriented along the y direction or the z direction. Since the direction of the crystal axis of aluminum oxide in the first block insulating layer 18 is oriented, the direction of the crystal axis of the second material in the barrier metal layer WLa formed on the first block insulating layer 18 is oriented.

By the manufacturing method according to the second embodiment described above, the direction of the crystal axis of aluminum oxide in the first block insulating layer 18 can be oriented along the z direction or the y direction. That is, by forming an aluminum oxide film by oxidizing an aluminum nitride film with a thickness less than 2.5 nm, the direction of the crystal axis of aluminum oxide can be oriented along the y direction or the z direction.

In addition, since the direction of the crystal axis of aluminum oxide in the first block insulating layer 18 and the direction of the crystal axis of the second material in the barrier metal layer WLa are oriented along the same direction, the crystal continuity at the interface between the first block insulating layer 18 and the barrier metal layer WLa is improved. Therefore, scattering of carriers at the interface between the first block insulating layer 18 and the barrier metal layer WLa can be suppressed. As a result, the electrical resistance of the word line WL can be reduced.

From the viewpoint of reducing the electrical resistance of the word line WL, it is preferable that the direction of the crystal axis of the first material in the metal layer WLb forming the word line WL falls within a range of ±5° with respect to the y direction or the z direction. In addition, from the viewpoint of reducing the electrical resistance of the word line WL, it is preferable that the direction of the crystal axis of the second material in the barrier metal layer WLa forming the word line WL falls within a range of ±5° with respect to the y direction or the z direction. In addition, from the viewpoint of reducing the electrical resistance of the word line WL, it is preferable that the direction of the crystal axis of aluminum oxide in the first block insulating layer 18 falls within a range of ±5° with respect to the y direction or the z direction.

In addition, the aluminum oxide contained in the first block insulating layer 18 includes at least one crystal phase selected from a group consisting of α-aluminum oxide and θ-aluminum oxide. Since the aluminum oxide contained in the first block insulating layer 18 includes at least one crystal phase selected from a group consisting of α-aluminum oxide and θ-aluminum oxide, the leakage current of the first block insulating layer 18 is reduced. The α-aluminum oxide and the θ-aluminum oxide have smaller leakage currents than other crystal phases, such as γ-aluminum oxide.

From the viewpoint of reducing the leakage current of the first block insulating layer 18, it is preferable that, among the crystal phases of aluminum oxide contained in the first block insulating layer 18, at least one crystal phase selected from a group consisting of α-aluminum oxide and θ-aluminum oxide is the main crystal phase. Being the main crystal phase means having a higher abundance ratio than other crystal phases.

The direction of the crystal axis of aluminum oxide in the first block insulating layer 18 falls within a range of ±10° with respect to the y direction or the z direction. That is, the aluminum oxide in the first block insulating layer 18 is uniaxially oriented. Since the aluminum oxide in the first block insulating layer 18 is uniaxially oriented, the leakage current of the first block insulating layer 18 is reduced. It is thought that leakage current can be reduced by increasing the crystallinity of aluminum oxide in the first block insulating layer 18.

From the viewpoint of reducing the leakage current of the first block insulating layer 18, it is preferable that the direction of the crystal axis of aluminum oxide in the first block insulating layer 18 falls within a range of ±5° with respect to the y direction or the z direction.

In the memory cell array 200 of the three-dimensional NAND flash memory according to the second embodiment, an aluminum oxide film formed by oxidizing a thick aluminum nitride film with a thickness equal to or more than 2.5 nm has an increased leakage current. When the thickness of the aluminum nitride film becomes equal to or more than 2.5 nm, the surface roughness after oxidation increases rapidly. The rapid increase in surface roughness is thought to be the cause of the increase in leakage current.

In the memory cell array 200 of the three-dimensional NAND flash memory according to the second embodiment, from the viewpoint of reducing the leakage current of the first block insulating layer 18, it is preferable that the thickness of the first block insulating layer 18 in the first direction is equal to or less than 2.0 nm.

### First Modification Example

A first modification example of the semiconductor memory device according to the second embodiment is different from the semiconductor memory device according to the second embodiment in that the first insulating layer is provided between the fifth insulating layer and the second insulating layer.

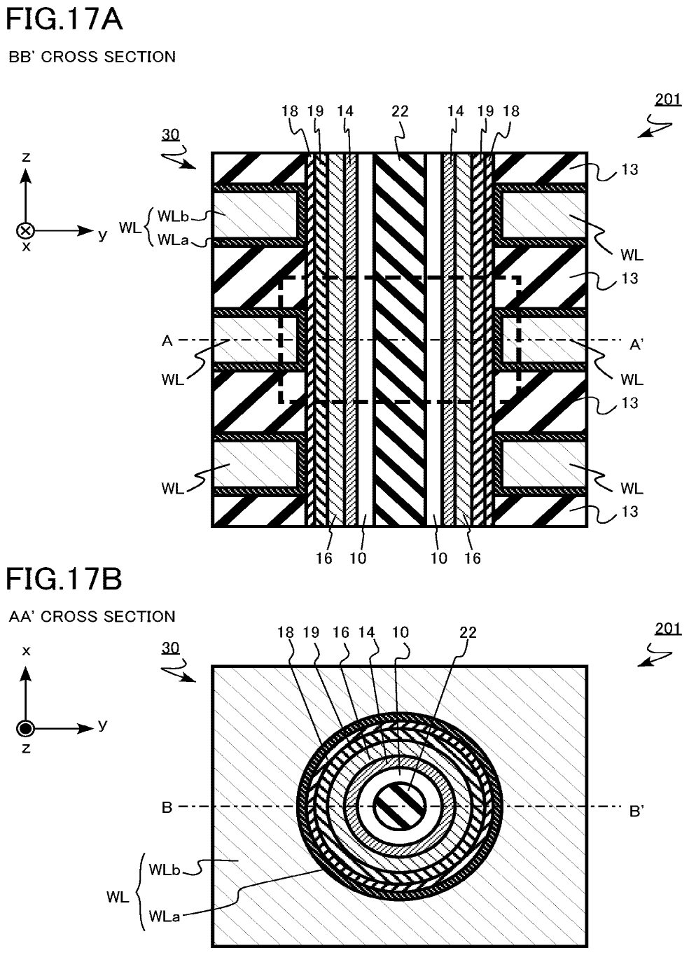

FIGS. 17A and 17B are schematic cross-sectional views of a memory cell array of the first modification example of the semiconductor memory device according to the second embodiment. FIGS. 17A and 17B show cross sections of a plurality of memory cells in one memory string MS. FIGS. 17A and 17B are diagrams corresponding to FIGS. 7A and 7B of the second embodiment.

In a memory cell array 201 of the first modification example, the first block insulating layer 18 is provided between the interlayer insulating layer 13 and the second block insulating layer 19.

The memory cell array 201 of the first modification example can be manufactured, for example, by forming the aluminum oxide film 78 before forming the silicon oxide film 66, which becomes the second block insulating layer 19, after forming the memory hole 64 in the method for manufacturing the memory cell array 200 according to the second embodiment.

### Second Modification Example

A second modification example of the semiconductor memory device according to the second embodiment is different from the semiconductor memory device according to the second embodiment in that a third insulating layer is further provided that is provided between the first insulating layer and the gate electrode layer and contains a third material having a higher dielectric constant than silicon oxide and different from aluminum oxide.

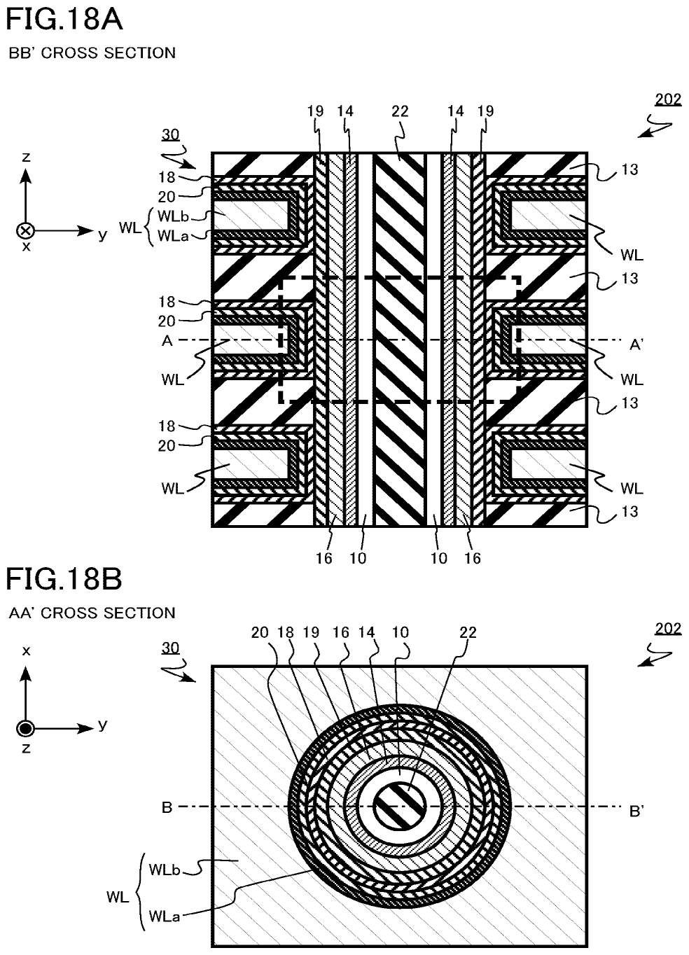

FIGS. 18A and 18B are schematic cross-sectional views of a memory cell array of the second modification example of the semiconductor memory device according to the second embodiment. FIGS. 18A and 18B show cross sections of a plurality of memory cells in one memory string MS. FIGS. 18A and 18B are diagrams corresponding to FIGS. 7A and 7B of the second embodiment.

A memory cell array 202 of the second modification example includes a high dielectric constant block insulating layer 20. The high dielectric constant block insulating layer 20 is an example of a third insulating layer.

The high dielectric constant block insulating layer 20 is provided between the word line WL and the semiconductor layer 10. In addition, the high dielectric constant block insulating layer 20 is provided between the word line WL and the interlayer insulating layer 13.

The high dielectric constant block insulating layer 20 is provided between the first block insulating layer 18 and the word line WL. The high dielectric constant block insulating layer 20 is provided between the first block insulating layer 18 and the barrier metal layer WLa. The high dielectric constant block insulating layer 20 is in contact with, for example, the first block insulating layer 18 and the barrier metal layer WLa.

The high dielectric constant block insulating layer 20 is an insulating layer. The high dielectric constant block insulating layer 20 contains a third material that has a higher dielectric constant than silicon oxide and is different from aluminum oxide.

The third material is the main component of the high dielectric constant block insulating layer 20. The high dielectric constant block insulating layer 20 is formed of, for example, a third material.

The third material is an insulator. The third material is, for example, at least one material selected from a group consisting of hafnium oxide, zirconium oxide, tantalum oxide, lanthanum oxide, and cerium oxide. The high dielectric constant block insulating layer 20 is, for example, a hafnium oxide layer, a zirconium oxide layer, a tantalum oxide layer, a lanthanum oxide layer, or a cerium oxide layer.

The direction of the crystal axis of the third material in the high dielectric constant block insulating layer 20 disposed between the word line WL and the semiconductor layer 10 falls within a range of ±10° with respect to the y direction from the semiconductor layer 10 toward the word line WL. The crystal axis of the third material is, for example, the a-axis, the b-axis, or the c-axis.

The crystal axis of the third material in the high dielectric constant block insulating layer 20 disposed between the word line WL and the semiconductor layer 10 is oriented along the y direction. The third material in the high dielectric constant block insulating layer 20 is uniaxially oriented. The direction of the c-axis of the third material in the high dielectric constant block insulating layer 20 falls within a range of ±10° with respect to the y direction, for example.

The direction of the crystal axis of the third material in the high dielectric constant block insulating layer 20 disposed between the word line WL and the interlayer insulating layer 13 falls within a range of ±10° with respect to the z direction in which the semiconductor layer 10 extends. The crystal axis of the third material is, for example, the a-axis, the b-axis, or the c-axis.

The crystal axis of the third material in the high dielectric constant block insulating layer 20 disposed between the word line WL and the interlayer insulating layer 13 is oriented along the z direction. The third material in the high dielectric constant block insulating layer 20 is uniaxially oriented. The direction of the c-axis of the third material in the high dielectric constant block insulating layer 20 falls within a range of ±10° with respect to the z direction, for example.

The angle between the direction of the crystal axis of the third material in the high dielectric constant block insulating layer 20 and the y direction or the z direction can be determined, for example, by comparing the arrangement direction of spots obtained by fast Fourier transform analysis of the TEM image of the cross section of the high dielectric constant block insulating layer 20 with the y direction or the z direction. For example, the angle between the spot arrangement direction and the y direction or the z direction is measured at a plurality of locations on the cross section of the high dielectric constant block insulating layer 20. Then, the average value of the measured angles is determined as the angle between the direction of the crystal axis of the third material in the high dielectric constant block insulating layer 20 and the y direction or as the angle between the direction of the crystal axis of the third material in the high dielectric constant block insulating layer 20 and the z direction.

The thickness of the high dielectric constant block insulating layer 20 in the y direction from the semiconductor layer 10 toward the word line WL is, for example, equal to or more than 0.5 nm and equal to or less than 2.5 nm.

According to the memory cell array 202 of the second modification example, since the high dielectric constant block insulating layer 20 is provided, the controllability of the memory operation is improved, for example.

As described above, according to the second embodiment and its modification examples, it is possible to provide a semiconductor memory device including a low-resistance gate electrode layer (word line).

### Third Embodiment

A semiconductor memory device according to a third embodiment is different from the semiconductor memory device according to the second embodiment in that the semiconductor layer extends in a direction parallel to the surface of the semiconductor substrate. Hereinafter, the description of a part of the content overlapping the second embodiment will be omitted.

The semiconductor memory device according to the third embodiment is a three-dimensional NAND flash memory. The memory cell of the semiconductor memory device according to the third embodiment is a so-called MONOS type memory cell.

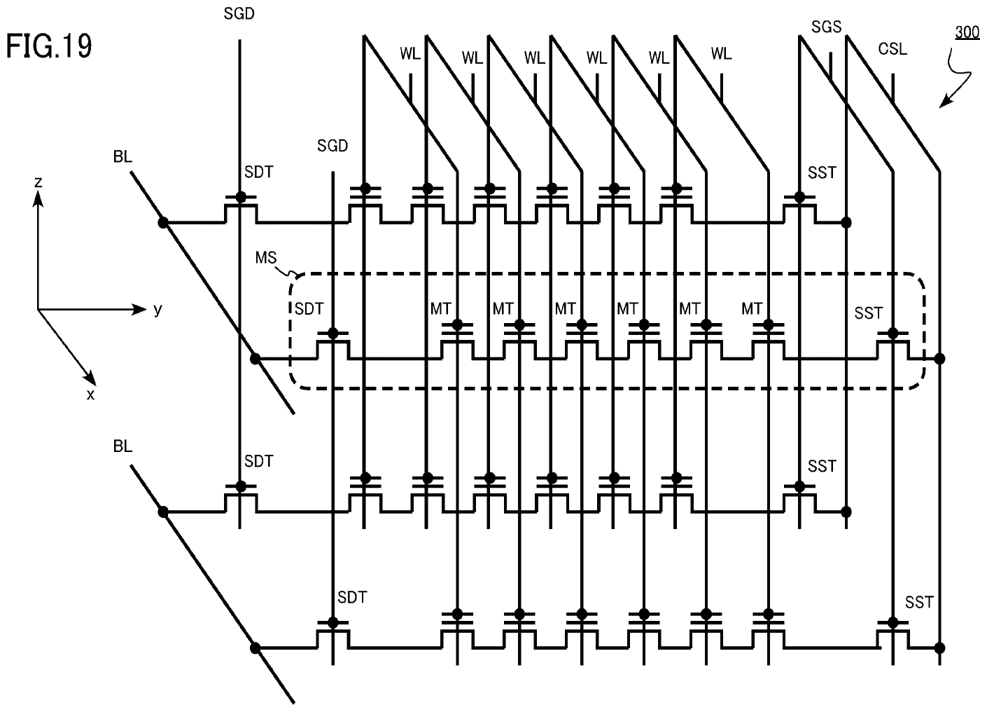

FIG. 19 is a circuit diagram of a memory cell array of the semiconductor memory device according to the third embodiment.

As shown in FIG. 19, a memory cell array 300 of the three-dimensional NAND flash memory according to the third embodiment includes a plurality of word lines WL, a common source line CSL, a source selection gate line SGS, a plurality of drain selection gate lines SGD, a plurality of bit lines BL, and a plurality of memory strings MS. The word line WL is an example of a gate electrode layer.

The plurality of word lines WL are arranged so as to be spaced from each other in the y direction. The plurality of memory strings MS extend in the y direction. The plurality of bit lines BL extend in the x direction, for example.

Hereinafter, the x direction is defined as a second direction, the y direction is defined as a first direction, and the z direction is defined as a third direction. The x direction, the y direction, and the z direction cross each other. For example, the x direction, the y direction, and the z direction are perpendicular to each other.

As shown in FIG. 19, each memory string MS includes a source selection transistor SST, a plurality of memory cells, and a drain selection transistor SDT connected in series to each other between the common source line CSL and the bit line BL. By selecting one bit line BL and one drain selection gate line SGD, one memory string MS is selected. Then, by selecting one word line WL, one memory cell can be selected. The word line WL is a gate electrode of the memory cell transistor MT forming the memory cell.

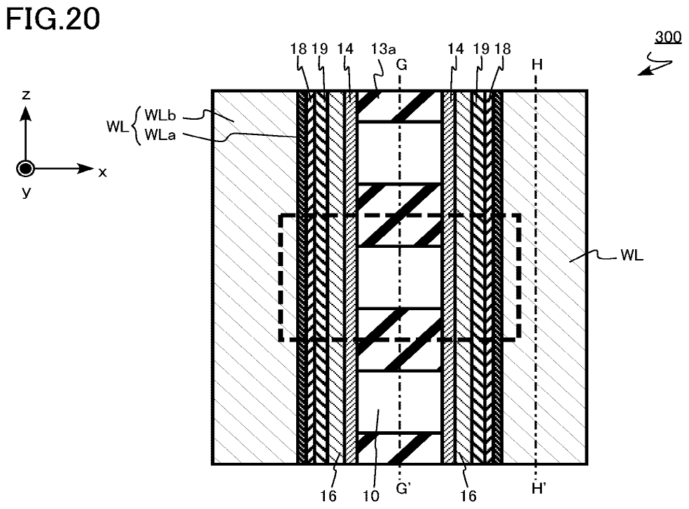

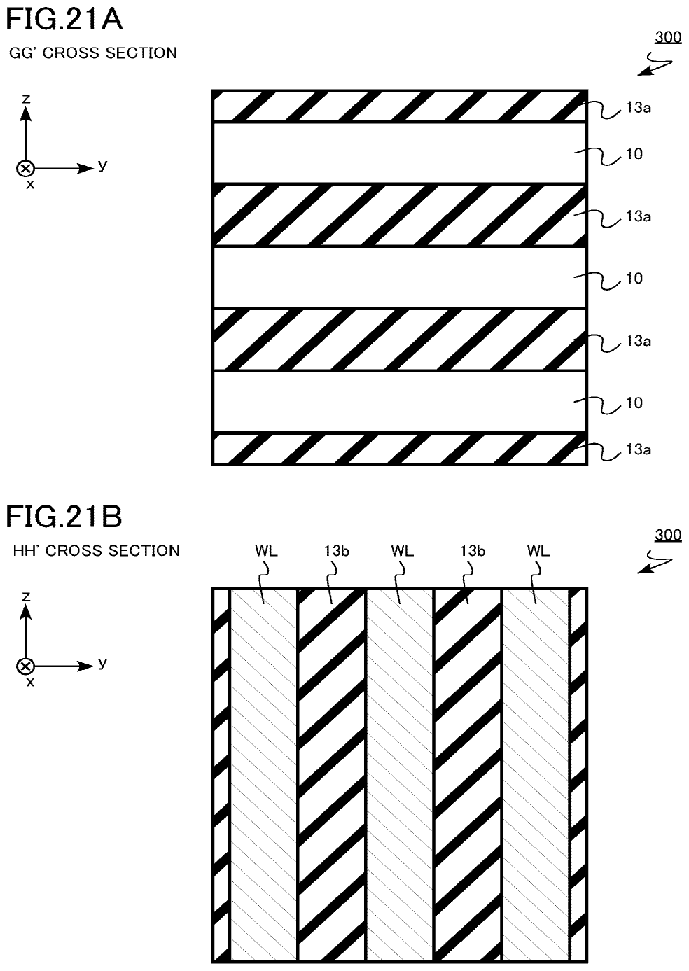

FIGS. 20, 21A, and 21B are schematic cross-sectional views of the memory cell array of the semiconductor memory device according to the third embodiment. FIGS. 20, 21A, and 21B show cross sections of a plurality of memory cells in a plurality of memory strings MS in the memory cell array 300 of FIG. 19.

FIG. 20 is an xz cross-sectional view of the memory cell array 300. In FIG. 20, the region surrounded by the broken line is one memory cell. FIG. 21A is a cross-sectional view taken along the line GG′ of FIG. 20. FIG. 21A is a yz cross-sectional view of the memory cell array 300. FIG. 21B is a cross-sectional view taken along the line HH′ of FIG. 20. FIG. 21B is a yz cross-sectional view of the memory cell array 300.

As shown in FIGS. 20, 21A, and 20B, the memory cell array 300 includes a word line WL, a semiconductor layer 10, a first interlayer insulating layer 13a, a second interlayer insulating layer 13b, a tunnel insulating layer 14, a charge storage layer 16, a first block insulating layer 18, and a second block insulating layer 19.

The word line WL is an example of a gate electrode layer. The tunnel insulating layer 14 is an example of a second insulating layer. The first block insulating layer 18 is an example of a first insulating layer. The second block insulating layer 19 is an example of a fourth insulating layer.

The word line WL includes a barrier metal layer WLa and a metal layer WLb. The barrier metal layer WLa is an example of a second conductive layer. The metal layer WLb is an example of a first conductive layer.

The memory cell array 300 is provided, for example, on a semiconductor substrate (not shown). The semiconductor substrate has, for example, a surface parallel to the x direction and the y direction.

As shown in FIG. 21B, the word line WL and the second interlayer insulating layer 13b are alternately arranged in the y direction on the semiconductor substrate. The word lines WL are arranged so as to be spaced from each other in the y direction. The word lines WL are repeatedly arranged in the y direction so as to be spaced from each other. The word line WL functions as a control electrode of the memory cell transistor MT.

The word line WL is, for example, a columnar conductor. The word line WL includes the barrier metal layer WLa and the metal layer WLb.

As shown in FIG. 20, the barrier metal layer WLa is provided between the metal layer WLb and the semiconductor layer 10. The barrier metal layer WLa is provided between the metal layer WLb and the first block insulating layer 18.

The metal layer WLb contains a first material. The barrier metal layer WLa contains a second material. The first material and the second material are different.

The first material is the main component of the metal layer WLb. The metal layer WLb is formed of, for example, a first material.

The first material is, for example, a metal or a metal compound. The first material is, for example, at least one material selected from a group consisting of molybdenum (Mo) and tungsten (W). The metal layer WLb is, for example, a molybdenum layer or a tungsten layer.

The second material is the main component of the barrier metal layer WLa. The barrier metal layer WLa is formed of, for example, a second material.

The second material is, for example, a metal or a metal compound. The second material is, for example, at least one material selected from a group consisting of molybdenum nitride, titanium nitride, and niobium nitride. The barrier metal layer WLa is, for example, a molybdenum nitride layer, a titanium nitride layer, or a niobium nitride layer.

As shown in FIGS. 20 and 21A, the first interlayer insulating layer 13a separates the semiconductor layers 10 from each other. The first interlayer insulating layer 13a electrically separates the semiconductor layers 10 from each other.

As shown in FIG. 21B, the second interlayer insulating layer 13b separates the word lines WL from each other. The second interlayer insulating layer 13b electrically separates the word lines WL from each other.

The first interlayer insulating layer 13a and the second interlayer insulating layer 13b are, for example, oxides, oxynitrides, or nitrides. The first interlayer insulating layer 13a and the second interlayer insulating layer 13b are, for example, silicon oxides. The thickness of the first interlayer insulating layer 13a in the z direction is, for example, equal to or more than 5 nm and equal to or less than 20 nm. The thickness of the second interlayer insulating layer 13b in the y direction is, for example, equal to or more than 5 nm and equal to or less than 20 nm.

The semiconductor layer 10 extends in the y direction. The semiconductor layer 10 extends in a direction parallel to the surface of the semiconductor substrate. The semiconductor layer 10 is interposed between a plurality of word lines WL. The semiconductor layer 10 has, for example, a quadrangular column shape. The semiconductor layer 10 functions as a channel of the memory cell transistor MT.

The semiconductor layer 10 is, for example, a polycrystal semiconductor. The semiconductor layer 10 is, for example, polycrystal silicon.

The tunnel insulating layer 14 is provided between the semiconductor layer 10 and the word line WL. The tunnel insulating layer 14 is provided between the semiconductor layer 10 and at least one of the plurality of word lines WL. The tunnel insulating layer 14 is provided between the semiconductor layer 10 and the charge storage layer 16.

The tunnel insulating layer 14 contains, for example, silicon (Si), nitrogen (N), and oxygen (O). The tunnel insulating layer 14 contains, for example, silicon oxide, silicon nitride, or silicon oxynitride.

The charge storage layer 16 is provided between the tunnel insulating layer 14 and the first block insulating layer 18. The charge storage layer 16 is provided between the tunnel insulating layer 14 and the second block insulating layer 19.

The charge storage layer 16 is, for example, an insulating layer. The charge storage layer 16 contains, for example, silicon (Si) and nitrogen (N). The charge storage layer 16 contains, for example, silicon nitride.

The first block insulating layer 18 and the second block insulating layer 19 are provided between the tunnel insulating layer 14 and the word line WL. The first block insulating layer 18 and the second block insulating layer 19 are provided between the charge storage layer 16 and the word line WL.

The first block insulating layer 18 is provided between the charge storage layer 16 and the word line WL. The first block insulating layer 18 is provided between the second block insulating layer 19 and the word line WL.

The first block insulating layer 18 is an insulating layer. The first block insulating layer 18 contains aluminum oxide. The first block insulating layer 18 is, for example, an aluminum oxide layer.

The aluminum oxide contained in the first block insulating layer 18 includes at least one crystal phase selected from a group consisting of α (alpha)-aluminum oxide and θ (theta)-aluminum oxide.

The direction of the crystal axis of aluminum oxide in the first block insulating layer 18 falls within a range of ±10° with respect to the x direction from the semiconductor layer 10 toward the word line WL. The crystal axis of aluminum oxide is, for example, the a-axis, the b-axis, or the c-axis.

The direction of the crystal axis of aluminum oxide in the first block insulating layer 18 is oriented along the x direction. The aluminum oxide in the first block insulating layer 18 is uniaxially oriented. The direction of the c-axis of aluminum oxide in the first block insulating layer 18 falls within a range of ±10° with respect to the x direction, for example.

The angle between the direction of the crystal axis of aluminum oxide in the first block insulating layer 18 and the x direction can be determined, for example, by comparing the arrangement direction of spots obtained by fast Fourier transform analysis of the TEM image of the cross section of the first block insulating layer 18 with the x direction. For example, the angle between the spot arrangement direction and the x direction is measured at a plurality of locations on the cross section of the first block insulating layer 18. Then, the average value of the measured angles is determined as the angle between the direction of the crystal axis of aluminum oxide in the first block insulating layer 18 and the x direction.

The thickness of the first block insulating layer 18 in the x direction from the semiconductor layer 10 toward the word line WL is, for example, equal to or more than 0.5 nm and equal to or less than 2.5 nm.

The direction of the crystal axis of the second material in the barrier metal layer WLa falls within a range of ±10° with respect to the x direction. The crystal axis of the second material is, for example, the a-axis, the b-axis, or the c-axis.

The crystal axis of the second material in the barrier metal layer WLa is oriented along the x direction. The second material in the barrier metal layer WLa is uniaxially oriented. For example, the direction of the c-axis of the second material in the barrier metal layer WLa falls within a range of ±10° with respect to the x direction.

The angle between the direction of the crystal axis of the second material in the barrier metal layer WLa and the x direction can be determined, for example, by comparing the arrangement direction of spots obtained by fast Fourier transform analysis of the TEM image of the cross section of the barrier metal layer WLa with the x direction. For example, the angle between the spot arrangement direction and the x direction is measured at a plurality of locations on the cross section of the barrier metal layer WLa. Then, for example, the average value of the measured angles is determined as the angle between the direction of the crystal axis of the second material in the barrier metal layer WLa and the x direction.

For example, the first block insulating layer 18 and the barrier metal layer WLa are in contact with each other. In addition, for example, the barrier metal layer WLa and the metal layer WLb are in contact with each other.

The direction of the crystal axis of the first material in the metal layer WLb falls within a range of ±10° with respect to the x direction. The crystal axis of the first material is, for example, the a-axis, the b-axis, or the c-axis.

The crystal axis of the first material in the metal layer WLb is oriented along the x direction. The first material in the metal layer WLb is uniaxially oriented. For example, the direction of the c-axis of the first material in the metal layer WLb falls within a range of ±10° with respect to the x direction.

The angle between the direction of the crystal axis of the first material in the metal layer WLb and the x direction can be determined, for example, by comparing the arrangement direction of spots obtained by fast Fourier transform analysis of the TEM image of the cross section of the metal layer WLb with the x direction. For example, the angle between the spot arrangement direction and the x direction is measured at a plurality of locations on the cross section of the metal layer WLb. Then, for example, the average value of the measured angles is determined as the angle between the direction of the crystal axis of the first material in the metal layer WLb and the x direction.

The second block insulating layer 19 is provided between the charge storage layer 16 and the first block insulating layer 18.

The second block insulating layer 19 is an insulating layer. The second block insulating layer 19 contains silicon (Si) and oxygen (O), for example. The second block insulating layer 19 contains silicon oxide, for example. The second block insulating layer 19 is, for example, a silicon oxide layer.

The thickness of the second block insulating layer 19 in the x direction is, for example, equal to or more than 3 nm and equal to or less than 8 nm.

According to the memory cell array 300 of the three-dimensional NAND flash memory according to the third embodiment, the electrical resistance of the word line WL can be reduced, similar to the memory cell array 200 of the three-dimensional NAND flash memory according to the second embodiment.

### Modification Examples

A modification example of the semiconductor memory device according to the third embodiment is different from the semiconductor memory device according to the third embodiment in that a third insulating layer is further provided that is provided between the first insulating layer and the gate electrode layer and contains a third material having a higher dielectric constant than silicon oxide and different from aluminum oxide.

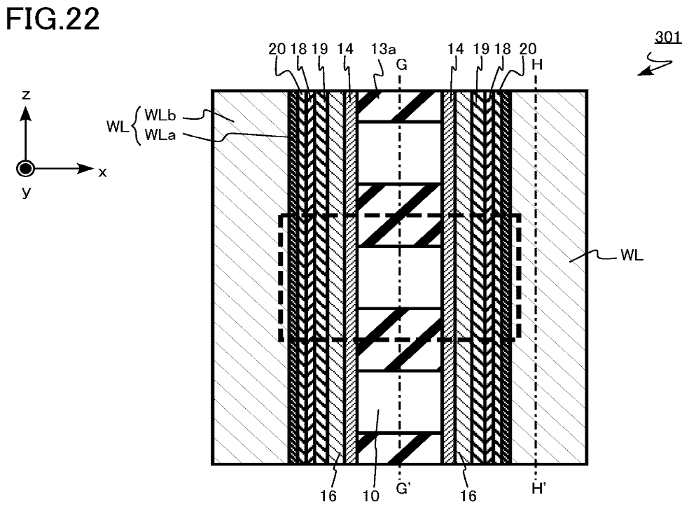

FIG. 22 is a schematic cross-sectional view of a memory cell array of the modification example of the semiconductor memory device according to the third embodiment. FIG. 22 shows cross sections of a plurality of memory cells in one memory string MS. FIG. 22 is a diagram corresponding to FIG. 20 of the third embodiment.

A memory cell array 301 of the modification example includes a high dielectric constant block insulating layer 20. The high dielectric constant block insulating layer 20 is an example of a third insulating layer.

The high dielectric constant block insulating layer 20 is provided between the word line WL and the semiconductor layer 10. The high dielectric constant block insulating layer 20 is provided between the first block insulating layer 18 and the word line WL. The high dielectric constant block insulating layer 20 is provided between the first block insulating layer 18 and the barrier metal layer WLa. The high dielectric constant block insulating layer 20 is in contact with, for example, the first block insulating layer 18 and the barrier metal layer WLa.

The high dielectric constant block insulating layer 20 is an insulating layer. The high dielectric constant block insulating layer 20 contains a third material that has a higher dielectric constant than silicon oxide and is different from aluminum oxide.

The third material is the main component of the high dielectric constant block insulating layer 20. The high dielectric constant block insulating layer 20 is formed of, for example, a third material.

The third material is an insulator. The third material is, for example, at least one material selected from a group consisting of hafnium oxide, zirconium oxide, tantalum oxide, lanthanum oxide, and cerium oxide. The high dielectric constant block insulating layer 20 is, for example, a hafnium oxide layer, a zirconium oxide layer, a tantalum oxide layer, a lanthanum oxide layer, or a cerium oxide layer.

The direction of the crystal axis of the third material in the high dielectric constant block insulating layer 20 disposed between the word line WL and the semiconductor layer 10 falls within a range of ±10° with respect to the x direction from the semiconductor layer 10 toward the word line WL. The crystal axis of the third material is, for example, the a-axis, the b-axis, or the c-axis.

The crystal axis of the third material in the high dielectric constant block insulating layer 20 is oriented along the x direction. The third material in the high dielectric constant block insulating layer 20 is uniaxially oriented. The direction of the c-axis of the third material in the high dielectric constant block insulating layer 20 falls within a range of ±10° with respect to the x direction, for example.

The angle between the direction of the crystal axis of the third material in the high dielectric constant block insulating layer 20 and the x direction can be determined, for example, by comparing the arrangement direction of spots obtained by fast Fourier transform analysis of the TEM image of the cross section of the high dielectric constant block insulating layer 20 with the x direction.

The thickness of the high dielectric constant block insulating layer 20 in the x direction from the semiconductor layer 10 toward the word line WL is, for example, equal to or more than 0.5 nm and equal to or less than 2.5 nm.

According to the memory cell array 301 of the modification example, since the high dielectric constant block insulating layer 20 is provided, the controllability of the memory operation is improved, for example.

As described above, according to the third embodiment and its modification examples, it is possible to provide a semiconductor memory device including a low-resistance gate electrode layer (word line).

In the second and third embodiments, the case where the interlayer insulating layer 13 is provided between the word lines WL has been described as an example. However, there may be a cavity between the word lines WL, for example.

In the second embodiment, the structure in which the semiconductor layer 10 is surrounded by the word line WL has been described as an example. However, it is also possible to have a structure in which the semiconductor layer 10 is interposed between the two divided word lines WL. In the case of this structure, the number of memory cells in the stacked body 30 can be doubled.

In addition, in the second embodiment, the structure in which one semiconductor layer 10 is provided in one memory hole has been described as an example. However, it is also possible to have a structure in which a plurality of semiconductor layers 10, which are two or more divided semiconductor layers, are provided in one memory hole. In the case of this structure, the number of memory cells in the stacked body 30 can be doubled or more.

In addition, in the second and third embodiments, the case where the charge storage layer is an insulating layer has been described as an example. However, the charge storage layer may be a conductive layer, for example, a plurality of floating conductive layers electrically separated from each other.

While certain embodiments have been described, these embodiments have been presented by way of example only, and are not intended to limit the scope of the inventions. Indeed, the semiconductor device and the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer;
a gate electrode layer including a first conductive layer containing a first material and a second conductive layer provided between the first conductive layer and the semiconductor layer and containing a second material different from the first material; and
a first insulating layer provided between the semiconductor layer and the gate electrode layer and containing aluminum oxide, the aluminum oxide including at least one crystal phase selected from a group consisting of α (alpha)-aluminum oxide and θ (theta)-aluminum oxide,
wherein a direction of a crystal axis of the aluminum oxide in the first insulating layer falls within a range of ±10° with respect to a first direction from the semiconductor layer toward the gate electrode layer,
a direction of a crystal axis of the first material in the first conductive layer falls within a range of ±10° with respect to the first direction, and
a direction of a crystal axis of the second material in the second conductive layer falls within a range of ±10° with respect to the first direction.

2. The semiconductor device according to claim 1,
wherein a thickness of the first insulating layer in the first direction is equal to or less than 2.5 nm.

3. The semiconductor device according to claim 1,
wherein the crystal axis is a c-axis.

4. The semiconductor device according to claim 1,
wherein the first material is at least one material selected from a group consisting of molybdenum (Mo) and tungsten (W), and
the second material is at least one material selected from a group consisting of molybdenum nitride, titanium nitride, and niobium nitride.

5. The semiconductor device according to claim 1, further comprising:
a second insulating layer provided between the semiconductor layer and the first insulating layer and containing silicon (Si) and oxygen (O).

6. The semiconductor device according to claim 1, further comprising:
a third insulating layer provided between the first insulating layer and the gate electrode layer and containing a third material having a higher dielectric constant than silicon oxide and different from aluminum oxide.

7. The semiconductor device according to claim 6,
wherein a direction of a crystal axis of the third material in the third insulating layer falls within a range of ±10° with respect to the first direction.

8. The semiconductor device according to claim 7,
wherein the third material is at least one material selected from a group consisting of hafnium oxide, zirconium oxide, tantalum oxide, lanthanum oxide, and cerium oxide.

9. A semiconductor memory device, comprising:
a semiconductor layer extending in a first direction;
a gate electrode layer including a first conductive layer containing a first material and a second conductive layer provided between the first conductive layer and the semiconductor layer and containing a second material different from the first material;
a charge storage layer provided between the semiconductor layer and the gate electrode layer;
a first insulating layer provided between the charge storage layer and the gate electrode layer and containing aluminum oxide, the aluminum oxide including at least one crystal phase selected from a group consisting of a (alpha)-aluminum oxide and θ (theta)-aluminum oxide; and
a second insulating layer provided between the charge storage layer and the semiconductor layer,
wherein a direction of a crystal axis of the aluminum oxide in the first insulating layer falls within a range of ±10° with respect to a second direction from the semiconductor layer toward the gate electrode layer,
a direction of a crystal axis of the first material in the first conductive layer falls within a range of ±10° with respect to the second direction, and
a direction of a crystal axis of the second material in the second conductive layer falls within a range of ±10° with respect to the second direction.

10. The semiconductor memory device according to claim 9,
wherein a thickness of the first insulating layer in the second direction is equal to or less than 2.5 nm.

11. The semiconductor memory device according to claim 9,
wherein the crystal axis is a c-axis.

12. The semiconductor memory device according to claim 9,
wherein the first material is at least one material selected from a group consisting of molybdenum (Mo) and tungsten (W), and
the second material is at least one material selected from a group consisting of molybdenum nitride, titanium nitride, and niobium nitride.

13. The semiconductor memory device according to claim 9, further comprising:
a third insulating layer provided between the first insulating layer and the gate electrode layer and containing a third material having a higher dielectric constant than silicon oxide and different from aluminum oxide.

14. The semiconductor memory device according to claim 13,
wherein a direction of a crystal axis of the third material in the third insulating layer falls within a range of ±10° with respect to the second direction.

15. The semiconductor memory device according to claim 14,
wherein the third material is at least one material selected from a group consisting of hafnium oxide, zirconium oxide, tantalum oxide, lanthanum oxide, and cerium oxide.

16. The semiconductor memory device according to claim 9, further comprising:
a fourth insulating layer provided between the charge storage layer and the first insulating layer and containing silicon (Si) and oxygen (O).

17. The semiconductor memory device according to claim 9, further comprising:
a fifth insulating layer,
wherein the gate electrode layer and the fifth insulating layer are arranged in the first direction, and
the first insulating layer is provided between the gate electrode layer and the fifth insulating layer.

18. The semiconductor memory device according to claim 17,
wherein a direction of a crystal axis of the aluminum oxide in the first insulating layer provided between the gate electrode layer and the fifth insulating layer falls within a range of ±10° with respect to the first direction.

19. The semiconductor memory device according to claim 9,
wherein the first insulating layer surrounds the semiconductor layer and the charge storage layer, the gate electrode layer surrounds the first insulating layer,
in a cross section perpendicular to the first direction, the first insulating layer has an annular shape, and a direction of a crystal axis of the aluminum oxide in the first insulating layer is radially oriented in a direction from an inside to an outside of the first insulating layer, and
in a cross section perpendicular to the first direction, a direction of a crystal axis of the first material in the first conductive layer and a direction of a crystal axis of the second material in the second conductive layer are radially oriented in a direction from the inside to the outside of the first insulating layer.
